(19) United States
(12) Patent Application Publication
(10) Pub. No.: US 2020/0350471 A1
(43) Pub. Date: Nov. 5, 2020

(54) LIGHT SOURCE DEVICE AND LIGHT EMITTING DEVICE

(71) Applicant: SHARP KABUSHIKI KAISHA, Sakai City (JP)

(72) Inventors: HIROAKI ONUMA, Sakai City (JP); NATHAN COLE, Oxford (GB); YUHSUKE FUJITA, Sakai City (JP); TAKASHI ONO, Sakai City (JP)

(21) Appl. No.: 16/853,524

(22) Filed: Apr. 20, 2020

Related U.S. Application Data
(60) Provisional application No. 62/840,843, filed on Apr. 30, 2019.

(51) Int. Cl. H01L 33/52; C09K 11/06

(52) U.S. Cl. CPC H01L 33/52; C09K 11/06

(57) ABSTRACT

A light source device includes a plurality of light emitting elements, phosphor layers provided for each of the plurality of light emitting elements at positions on emission sides of light from the light emitting elements and parts of which are in contact with the light emitting elements, light shielding layers different from the phosphor layers, and reinforcement layers provided between the light emitting elements.

### CROSS-REFERENCE TO RELATED APPLICATION

The present application claims priority from Provisional Application 62/840,843, the content to which is hereby incorporated by reference into this application.

### TECHNICAL FIELD

The present invention relates to a light source device and a light emitting device including a light emitting element and a phosphor layer.

### BACKGROUND ART

For example, a micro semiconductor light emitting element (light emitting diode; LED) display device disclosed in Japanese Patent No. 6383074 is known as a device including a light emitting element and a phosphor layer. In the above-described display device, a layer of a light emitting structure is provided via a bump on a driver circuit (complementary metal-oxide-semiconductor; CMOS) cell on a drive substrate, a growth substrate is provided thereon, and a plurality of color light conversion material layers are provided on the growth substrate. The color light conversion material layers are individually separated by partition walls.

### SUMMARY OF INVENTION

### Technical Problem

The above-described display device of related art cannot be applied to a configuration of a light source device having a light emitting element instead of a layer of a light emitting structure for each color light conversion material layer of each color. Such a light source device has a configuration in which, for example, a plurality of light emitting elements are provided on a base substrate via electrodes, and phosphor layers are provided on the light emitting elements. Furthermore, in such a light source device, a display pixel size of several tens to several microns is required to be miniaturized, and accordingly, bonding areas between the light emitting elements to be pixels and a base substrate including a circuit are reduced, and thus, the light emitting elements are easily peeled off from the base substrate during a manufacturing process. In addition to this, the above-described display device of related art has a problem that it is difficult to realize a sufficient color reproduction range as a display. This leads to a problem that a color conversion layer formed on the light emitting element is easily peeled off because a thickness of the color conversion layer is obtained with a small bonding area, that is, the color conversion layer is formed with a high aspect ratio.

An aspect of the present invention is to realize a light source device and a light emitting device having a sufficient color reproduction range as a display by having characteristics in which a light emitting element is hardly peeled off from a base substrate during a manufacturing process and characteristics in which a color conversion layer formed on the light emitting element is hardly peeled off, in the light source device having a configuration in which the light emitting element is provided for each color phosphor layer on the base substrate.

### Solution to Problem

In order to solve the above problem, a light source device according to one aspect of the present invention includes a plurality of light emitting elements, phosphor layers provided for each of the light emitting elements at positions on emission sides of light from the light emitting elements and parts of which are in contact with the light emitting elements, light shielding layers that are provided between the phosphor layers adjacent to each other and are different from the phosphor layers, and reinforcement layers provided between the light emitting elements adjacent to each other.

### Advantageous Effects of Invention

According to one aspect of the present invention, a display having a fine pixel size of several tens to several microns and a high color reproduction range can be realized, and a light emitting element can be hardly peeled off from a base substrate, and a color conversion layer formed on the light emitting element can be hardly peeled off.

### BRIEF DESCRIPTION OF DRAWINGS

FIG. 1 is a longitudinal cross-sectional diagram illustrating a configuration of a light source device according to an embodiment of the present invention.

FIG. 2 is an explanatory diagram illustrating a material of a light shielding layer illustrated in FIG. 1, and a function and an effect when the material is used.

FIG. 3 is a longitudinal cross-sectional diagram illustrating a configuration of a light source device according to another embodiment of the present invention.

FIG. 4(a) is an explanatory diagram when light emitting elements are short-circuited by a light shielding layer formed of a metal that straddles an adjacent light emitting element, in a light source device without a base layer (described in FIG. 3). FIG. 4(b) is an explanatory diagram when the short-circuit illustrated in FIG. 4(a) is prevented by the base layer, in the light source device including the base layer illustrated in FIG. 3 and the light shielding layer illustrated in FIG. 4(a).

FIG. 5 is a longitudinal cross-sectional diagram illustrating a configuration of a light source device according to still another embodiment of the present invention.

FIG. 6 is a longitudinal cross-sectional diagram illustrating a configuration of a light source device according to still another embodiment of the present invention.

FIG. 7 is a longitudinal cross-sectional diagram illustrating a configuration of a light source device according to still another embodiment of the present invention.

FIG. 8 is a longitudinal cross-sectional diagram illustrating a configuration of a light source device according to still another embodiment of the present invention.

FIG. 9 is a longitudinal cross-sectional diagram illustrating a configuration of a light source device according to still another embodiment of the present invention.

FIG. 10 is a longitudinal cross-sectional diagram illustrating a configuration of a light source device according to still another embodiment of the present invention.

FIG. 11 is a longitudinal cross-sectional diagram illustrating a configuration of a light source device according to a modification example of the light source device illustrated in FIG. 10.

FIG. 12 is a longitudinal cross-sectional diagram illustrating a configuration of a light source device according to another modification example of the light source device illustrated in FIG. 10.

FIG. 13 is a longitudinal cross-sectional diagram illustrating a configuration of a light source device according to still another modification example of the light source device illustrated in FIG. 10.

FIG. 14 is a longitudinal cross-sectional diagram illustrating a configuration of a light source device according to still another embodiment of the present invention.

FIG. 15 is a longitudinal cross-sectional diagram illustrating a configuration of a light source device according to a modification example of the light source device illustrated in FIG. 14.

FIG. 16 is a longitudinal cross-sectional diagram illustrating a configuration of a light source device according to still another embodiment of the present invention.

FIG. 17 is a longitudinal cross-sectional diagram illustrating a configuration of a light source device according to a modification example of the light source device illustrated in FIG. 16.

FIG. 18 is a longitudinal cross-sectional diagram illustrating a configuration of a light source device according to another modification example of the light source device illustrated in FIG. 16.

FIG. 19 is a longitudinal cross-sectional diagram illustrating a method of manufacturing the light source device according to the embodiment of the present invention.

FIG. 20 is a longitudinal cross-sectional diagram illustrating another method of manufacturing the light source device according to the embodiment of the present invention.

FIG. 21 is a longitudinal cross-sectional diagram illustrating still another method of manufacturing the light source device according to the embodiment of the present invention.

FIG. 22 is a longitudinal cross-sectional diagram illustrating still another method of manufacturing the light source device according to the embodiment of the present invention.

FIG. 23 is a longitudinal cross-sectional diagram illustrating still another method of manufacturing the light source device according to the embodiment of the present invention.

FIG. 24 is a longitudinal cross-sectional diagram illustrating still another method of manufacturing the light source device according to the embodiment of the present invention.

FIG. 25 is a longitudinal cross-sectional diagram illustrating still another method of manufacturing the light source device according to the embodiment of the present invention.

FIG. 26 is a longitudinal cross-sectional diagram illustrating still another method of manufacturing the light source device according to the embodiment of the present invention.

FIG. 27 illustrates an effect of a light shielding layer of a light source device according to an example of the light source device illustrated in FIG. 14.

FIG. 28 is a longitudinal cross-sectional diagram illustrating an example of a cross-sectional structure of the light emitting element included in the light source device according to the embodiment of the present invention.

FIG. 29 is a longitudinal cross-sectional diagram illustrating another example of the cross-sectional structure of the light emitting element included in the light source device according to the embodiment of the present invention.

FIG. 30 is a flowchart illustrating a process of manufacturing the light emitting element illustrated in FIG. 28.

### DESCRIPTION OF EMBODIMENTS

### First Embodiment

(Configuration of Light Source Device 1)

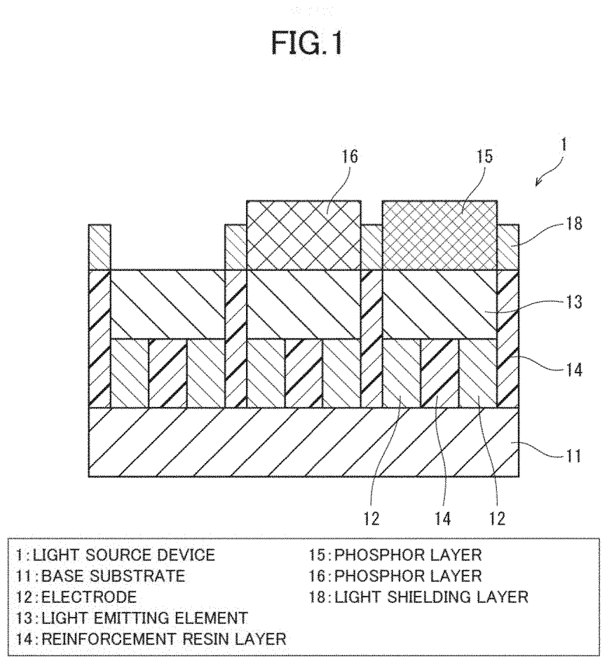

Hereinafter, an embodiment of the present invention will be described in detail. FIG. 1 is a longitudinal cross-sectional diagram illustrating a configuration of a light source device 1 according to the present embodiment.

As illustrated in FIG. 1, the light source device 1 includes a base substrate 11, electrodes 12, light emitting elements 13, reinforcement resin layers (reinforcement layers) 14, phosphor layers 15 and 16, and light shielding layers 18. In the present embodiment, the light source device 1 includes three light emitting elements 13.

In the figure, there are three light emitting elements 13, and there is one pixel, that is, only three sub-pixels respectively corresponding to red, green and blue, but the light emitting elements 13 are originally light emitting elements having an array shape of m rows and n columns (m and n are integers of 2 or greater). m and n may be set randomly according to the purpose, and for example, if a light emitting element array of 720 rows and 1280 columns×3 (for each color of red, green, and blue) is used, a high definition (HD) color image or an HD moving image can be displayed. If a light emitting element array of 1080 rows and 1920 columns×3 (for each color of red 1, green 1, and blue 1) is used, a full HD (Fu 11 High Definition) color image or moving image can be displayed. The number of subpixels of red, green, and blue that configure one pixel is not limited to one, and for example, may be 1080 rows and 1920 columns×4 (each component of red 2, green 1, and blue 1), and 1080 rows and 1920 column×5 (each component of red 2, green 1, and blue 2), 1080 rows and 1920 columns×6 (each component id red 2, green 2, blue 2), and the like. The light emitting elements in a plurality of vertical rows and a plurality of horizontal columns on the outer peripheral side of the array may be formed so as not to be lit or may be bonded to the base substrate. Thereby, it is possible to set environments of the light emitting elements to be lit in the array to be the same as each other.

A bonding area between the base substrate and the light emitting element array can be increased, and a bonding strength can be increased. In addition to this, when forming the light shielding layer or the phosphor layer, a non-light element on an outer periphery may be used as a mark for alignment. The same applies to the second and subsequent embodiments.

(Base Substrate 11)

The base substrate 11 includes wires formed on at least a surface thereof so as to be able to be connect to the light emitting elements 13. A drive circuit for driving the light emitting elements 13 is formed on the base substrate 11. A material of the base substrate 11 is preferably a crystalline substrate of a single crystal, polycrystal, or the like of aluminum nitride composed entirely of aluminum nitride, and a sintered substrate. The material of the base substrate 11 is preferably a semi-metal or metal substrate of ceramics such as alumina, glass, si, or the like, and a stacked body or a composite such as a substrate having an aluminum nitride thin film layer formed on a surface thereof can be used. The metal substrate and the ceramic substrate are preferable as the material of the base substrate 11 because of their high heat dissipation. In the present embodiment, the base substrate 11 is formed of si.

For example, it is possible to manufacture the high-resolution light source device 1 in which fine light emitting elements 13 are densely integrated by using a drive circuit for controlling light emission of the light emitting element 13 formed on Si by an integrated circuit forming technology, as the base substrate 11.

(Electrode 12)

The electrode 12 electrically connects the base substrate 11 to the light emitting element 13 and includes an electrode on the base substrate 11 side and an electrode on the light emitting element 13 side. The electrode 12 is formed of any one of, for example, Au, Pt, Pd, Rh, Ni, W, Mo, Cr, and Ti, an alloy thereof, or a combination thereof. As an example of the combination, when an electrode on the base substrate 11 side and an electrode on the light emitting element 13 side are configured as a metal electrode layer, a stacked structure of W/Pt/Au, Rh/Pt/Au, W/Pt/Au/Ni, Pt/Au, Ti/Pt/Au, Ti/Rh, or TiW/Au from a lower surface is considered. In the present embodiment, the electrode 12 is formed of Au.

(Light Emitting Element 13)

A known light emitting element, specifically, a semiconductor light emitting element (LED chip) can be used as the light emitting element 13. For example, a GaAs-based material, a ZnO-based material, or a GaN-based material is used. As the light emitting element 13, an LED that emits lights of red, yellow, green, blue, or violet may be used, or an LED that emits ultraviolet light may be used. Among them, it is preferable to use a GaN-based semiconductor capable of emitting blue to purple light or purple to ultraviolet light as the light emitting element 13. In the present embodiment, the light emitting element 13 is formed of InGaN and emits blue light. A top surface of the light emitting element 13 is a light emitting surface in FIG. 1. The above points of the light emitting element 13 are the same in other embodiments to be described below.

A GaN-based semiconductor is preferable as the light emitting element 13 because the semiconductor has characteristics of high light emission efficiency, a long life span, and a high reliability. A semiconductor layer of the light emitting element 13 is preferably used in a point that a nitride semiconductor is in the short wavelength region of a visible light region, a near ultraviolet region, or a shorter wavelength region, and in the semiconductor module 1 obtained by combining the point and a wavelength conversion member (phosphor). The present invention is not limited thereto, and a semiconductor based on ZnSe, InGaAs, AlInGaP, or the like may be used.

A structure of the light emitting element configured with a semiconductor layer is preferably a structure having an active layer between a first conductivity type (n type) layer and a second conductivity type (p type) layer in terms of output efficiency but is not limited thereto. Each conductivity type layer may be partially provided with insulating, semi-insulating, and reverse conductivity type structures or may be a structure in which the structure is additionally provided to first and second conductivity type layers. Another circuit structure, for example a protection element structure may be additionally included therein.

The structures of the light emitting element 13 and a semiconductor layer thereof may have a homostructure having a PN junction, a heterostructure, or a double heterostructure. Each layer may have a superlattice structure, and a single quantum well structure or a multiple quantum well structure in which a light emitting layer that is an active layer is formed as a thin film in which a quantum effect occurs. An interval between adjacent light emitting elements 13 is preferably 0.1 μm or greater and 20 μm or less. In this case, a thickness of the reinforcement resin layer 14 existing between the light emitting elements 13 and a thickness of the light shielding layer 18 existing on the reinforcement resin layer 14 are 0.1 μm or greater and 20 μm or less. A surface configured by the light emitting element 13 and the reinforcement resin layer 14 may have a flat shape with substantially the same height, which makes it possible to easily form the phosphor layers 15 and 16 and the light shielding layer 18. Meanwhile, a surface configured by the light emitting element 13 and the reinforcement resin layer 14 may form a specified periodic structure such as a rough surface or a concavo-convex surface, and since a contact area between the phosphor layers 15 and 16 and the light shielding layer 18, and the light emitting element 13 increases, peeling of the phosphor layers 15 and 16 and the light shielding layer 18 can be suppressed. These are not described in other embodiments but are the same in other embodiments without being limited to the present embodiment.

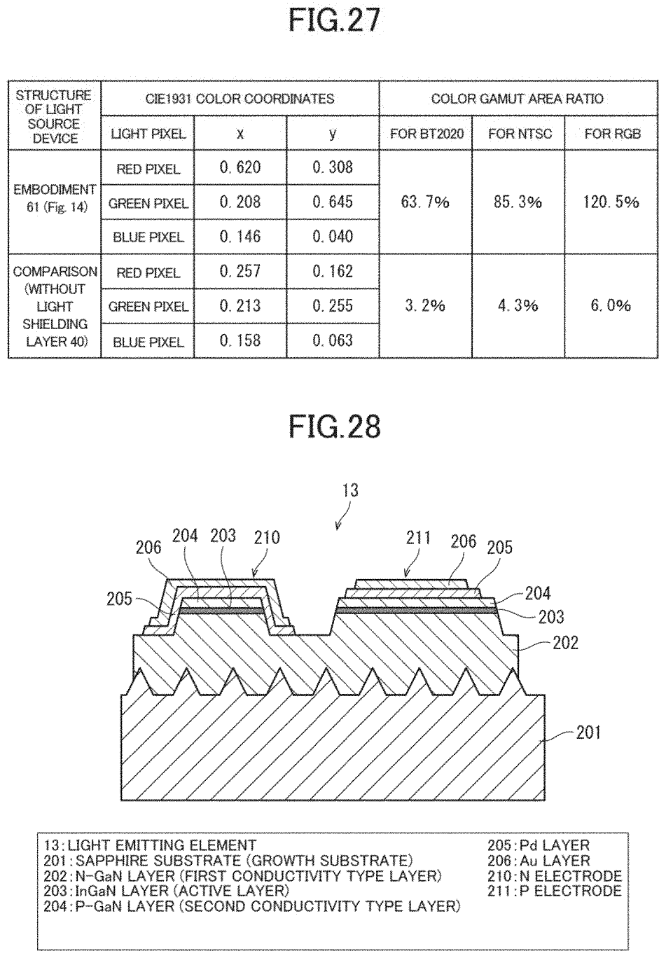

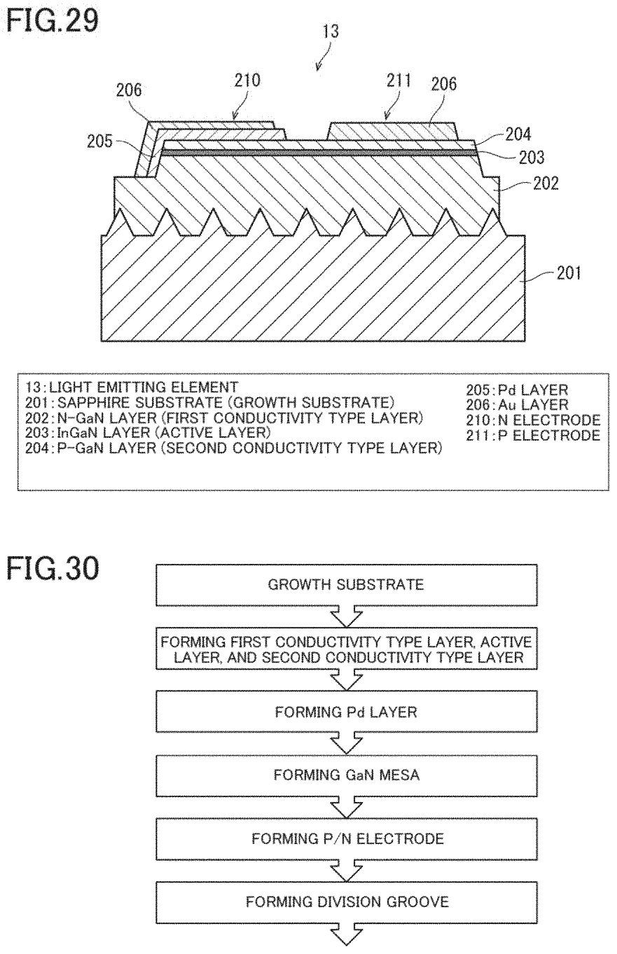

In addition, since the light emitting element 13 is bonded to the base substrate 11 via the electrode 12, it is desirable that an N electrode and a P electrode on the light emitting element 13 have substantially the same height. In order to realize this structure, it is conceivable to adopt a mesa structure for one or both of the N electrode and the P electrode, or to adopt a common mesa structure for the N electrode and the P electrode. A cross-sectional structure of the light emitting element 13, which employs the mesa structure, before bonding may be as illustrated in, for example, FIG. 28 or 29.

In FIGS. 28 and 29, 201 is a sapphire substrate (growth substrate), 202 is an N—GaN layer (first conductivity type layer), 203 is an InGaN layer (active layer), and 204 is a P—GaN layer (second conductivity type layer), 205 is a Pd layer, 206 is an Au layer, 210 is an N electrode, and 211 is a P electrode.

FIG. 30 illustrates a flowchart of a manufacturing process of the light emitting element 13 when a mesa structure is adopted for both the N electrode and the P electrode as illustrated in FIG. 28. In FIGS. 28 and 29, the Pd layer 205 and the Au layer 206 form the N electrode 210 and the P electrode 211, but if the N electrode 210 and the P electrode 211 can be formed at substantially the same height, the N electrode 210 and the P electrode 211 may be formed of other conductive materials such as pt, Al, Ag, and ITO transparent electrode without being limited to Pd or Au. In FIGS. 28 and 29, the sapphire substrate 201 having a patterned sapphire substrate (PSS) shape is used as a growth substrate.

The growth substrate may be other materials such as a GaN substrate and an si substrate, or may be a growth substrate having no PSs shape.

The light emitting elements 13 may be separated into individual pieces to correspond to the sub-pixels and thereafter respectively bonded to the base substrate 11 to separate the growth substrate, or may respectively bond the light emitting elements 13 which are separated into pieces to correspond to the sub-pixels after separating the growth substrate, to the base substrate 11, or the light emitting elements 13 may be formed on the growth substrate, divided into array chips having the number of light emitting element sub-pixels corresponding to an image display, and then the growth substrate may be peeled off after the array is bonded together. In this case, the growth substrate is peeled off by ultraviolet laser irradiation, grinding, polishing, chemical treatment, or the like. As such, when the light emitting elements 13 are collectively bonded as an array and the growth substrate is peeled off, or when the growth substrate is peeled off after the light emitting elements 13 separated into individual pieces are bonded, the peeling of the light emitting elements 13 from the base substrate 11 is suppressed, and thus, it is preferable to bond the light emitting element array bonded to the base substrate 11 after the array is formed, and to peel the growth substrate after the reinforcement resin is filled between the base substrate 11 and the light emitting elements 13 and between the light emitting elements 13 as will be described below. This is because a bonding strength between the light emitting element and the base substrate can be increased by existence of the reinforcement resin. In addition to this, light extraction can be increased by cleaning residues existing at an interface between the growth substrate and GaN through polishing after peeling of growth substrate, or a cleaning process using chemical solution or water. By processing after the peeling, in a case of having a PSS shape, it is possible to obtain a structure that realizes a desired light extraction by controlling a way of retaining the PSS shape or a thickness of the GaN layer.

In the present embodiment, each of the light emitting elements 13 corresponding to the sub-pixels includes both an N electrode and a P electrode and is spatially divided. The light emitting element 13 corresponding to the sub-pixel may include only the P electrode, first conductivity type layers of the plurality of light emitting elements 13 may be connected, and the N electrodes corresponding to the plurality of sub-pixels may be formed in different places. For example, one pixel, that is, a common N-electrode may be formed in each if the light emitting elements 13 corresponding to the three sub-pixels, or the common N-electrode may be formed for the number of light emitting elements 13 corresponding to more sub-pixels. In addition, a formation position of the common N electrode is not limited and may be in a display screen position or may be formed on an outer periphery of a region corresponding to the display screen. In the above-described configuration, if the first conductivity type layer connecting the plurality of light emitting elements 13 is thick, the amount of light of the light emitting element 13 passing therethrough increases.

Thus, since there is a possibility that crosstalk is generated in which a color reproduction range is reduced due to existence of light transmitted through adjacent pixels when each sub-pixel is lit, which is disadvantageous from a viewpoint of the color reproduction range, a division groove is formed for each sub-pixel, or a thin film is formed by polishing or chemical solution processing. Even at a point where a high-definition image is obtained because the crosstalk increases an effective size of each sub-pixel at the time of lighting, the first conductive layer connecting the light emitting elements is preferably thin, that is, preferably 10 μm or less, more preferably 5 μm or less, and still more preferably 2 μm or less. Meanwhile, if a step of thinning the first conductivity type layer is not performed, there is a possibility that a light emitting element with higher efficiency can be obtained by reducing a merit of reducing an operation time or reducing the processing.

Although the above description is not made in detail hereinafter, the same applies to a second embodiment and thereafter, and if the light emitting element 13 can be bonded to the base substrate 11 without peeling, the structures of the N electrode and the P electrode, a relative positional relationship and a numerical corresponding relationship, a material forming the light emitting element 13, a method for forming the light emitting element 13 and the light emitting element array, and a processing method including the growth substrate and the light emitting element after bonding are not limited to the above description.

(Reinforcement Resin Layer 14)

The reinforcement resin layer 14 is formed to fill a space between the adjacent light emitting elements 13 with a reinforcement resin. In addition to this, in the present embodiment, the reinforcement resin layer 14 is formed to fill a space between the light emitting element 13 and the base substrate 11 and a space between the adjacent electrodes 12 with the reinforcement resin. In the present embodiment, an upper surface of the reinforcement resin layer 14 between the adjacent light emitting elements 13 has substantially the same height as an upper surface of the light emitting element 13. The reinforcement resin layer 14 suppresses peeling of the light emitting element 13, and a height of the upper surface is not limited to this and may be formed to be lower or higher than a height of the upper surface of the light emitting element 13. The light emitting element 13 is peeled off from the electrode 12 or from the electrode 12 and the base substrate, or the light emitting element 13 falls down by external force at the time of the above-described peeling the growth substrate, at the time of polishing or cleaning residues after the peeling, or at the time of forming a light shielding layer or a phosphor layer which will be described below, or a vibration at the time of using the light source device, and thus, the light emitting element 13 can be peeled off. The reinforcement resin layer 14 has an effect of suppressing peeling of the light emitting element 13 from the base substrate 11 during a manufacturing process or during use of the light source device. By adding a light absorbing material such as plaque carbon, or a light scattering material such as SiO₂ or TiO₂ to the reinforcement resin, or by selecting an appropriate resin component, it is possible to retain light shielding properties such as light absorption or light reflection and to reduce a mutual light interference between the respective sub-pixels in the light source device according to the embodiment, that is, influence of crosstalk. Since the reinforcement resin needs to be filled between the light emitting elements 13, a size of the additive material is 1 μm or less, preferably 0.1 μm or less, more preferably 0.05 μm or less.

In the light source device 1, by covering a side surface of the light emitting element 13 with the reinforcement resin layer 14, the following actions and effects can be obtained in addition to peeling and suppressing of the light emitting element 13. First, it is possible to prevent light from leaking from a side surface of the light emitting element 13. Second, light having a color difference that is not negligible compared to light emission from a light emitting surface of the light emitting element 13 is suppressed from being emitted outward from a side surface of the light emitting element 13, and thus, occurrence of color unevenness in the entire emission color of the light emitting device 1 can be reduced. Third, when the reinforcement resin layer 14 has a light reflection function, light that progresses in a side direction of the light emitting element 13 is reflected by the reinforcement resin layer 14 toward a light extraction direction of the light source device 1, and further a light emitting region to the outside is restricted. Thereby, directivity of the light emitted from the light emitting element 13 increases, and the light emission luminance on the light emitting surface of the light emitting element 13 increases. Fourth, by dissipating heat generated by the light emitting element 13 to the reinforcement resin layer 14, heat dissipation of the light emitting element 13 can be enhanced. Fifth, by forming the reinforcement resin layer 14, a light emitting layer of the light emitting element 13 can be protected from water or oxygen.

In addition, the reinforcement resin layer 14 suppresses peeling of the light emitting element from the base substrate, and a configuration thereof is not limited to organic materials such as resin, and the reinforcement resin layer an inorganic reinforcement layer formed of an inorganic material such as Si, Al, Au, Ag, Cu, Pt, Pd, Al₂O₃, SiO₂, TiO₂, GaN, InGaN, and AlGaN. A plurality of materials may be formed of one or both of an organic material and an inorganic material. when the inorganic reinforcement layer is used, after the inorganic reinforcement layer is formed on the base substrate 11 side, or after the inorganic reinforcement layer is formed previously on a side surface of the sub-pixel of the light emitting element 13, the base substrate, it is considered that the base substrate, the light emitting element, and the reinforcement layers are simultaneously bonded.

(Phosphor Layers 15 and 16)

In the present embodiment, the phosphor layer 15 is formed of a red phosphor, and the phosphor layer 16 is formed of a green phosphor. The phosphor layer 15 is provided on an upper surface of the middle light emitting element 13 of the three light emitting elements 13 included in the light source device 1 and in a range of an upper surface of the light emitting element 13. The phosphor layer 16 is provided on the upper surface of the light emitting element 13 on one end side of the three light emitting elements 13 included in the light source device 1 and in a range of the upper surface of the light emitting element 13. As such, in the light source device 1, various light emission colors in a visible light region are illustrated by arranging the phosphor layers 15 and 16 having a different light emission color from the light emission color of the light emitting element 13 on the upper surface of the light emitting element 13 as described above.

The phosphor layers 15 and 16 are formed of ceramic phosphors such as Y₃Al₅O₁₂:Ce³⁺, Y₃ (Al, Ga)₅O₁₂:Ce³⁺, Lu₃Al₅O₁₂: Ce³⁺, (Sr, Ba)₂SiO₄:Eu²⁺, Ca₂SiO₄:Eu²⁺, Ca₃(Sc, Mg)₂Si₃O₁₂: Ce³⁺, {β-SiAlON: Eu²⁺, Ca-α-SiAlON: Eu²⁺, La₃Si₆N₁₁:Ce³⁺, SiF₆:Mn⁴⁺, CaAlSiN₃:Eu²⁺, (Sr, Ca) AlSiN₃:Eu²⁺, and (Ba, Sr)₂Si₅Ne:Eu²⁺, quantum dots such as CdSe, CdS, ZnS, ZnSe, CdTe, InP, InGaP, GaP, and (MA_{y}FA_{1-y}) PbX₃ (MA=methylammonium such as CH₃NH₃, FA=formamidine such as CH(NH₂)₂, X=Cl, Br, I), and Cs₃Cu₂I₅, a phosphor material such as GaN or InGaN, a color conversion material such as a light absorbing material, a light scattering material such as titania, silica, or alumina, a resin serving as a base material, and the like, and converts a wavelength of the light emitted from the light emitting element 13. The phosphor layer 15 converts light emitted from the light emitting element 13 into red light, and the phosphor layer 16 converts light emitted by the light emitting element 13 into green light.

An interval between the adjacent phosphor layers 15 and 16 is preferably 0.1 μm or more and 20 μm or less. The phosphor layers 15 and 16 preferably include a phosphor having a median diameter of 2 μm or less, preferably include a phosphor having a median diameter of 0.5 μm or less, and more preferably include a phosphor having a median diameter of 0.15 μm or less. In this case, since sizes of the phosphor layers 15 and 16 can be reduced, a pixel size of the light source device 1 can be reduced, and a higher definition image can be displayed.

(Light Shielding Layer 18)

The light shielding layer 18 is provided on the reinforcement resin layer 14 and covers a periphery of each side surface of the phosphor layers 15 and 16. The light shielding layer 18 can be formed, for example, by applying, exposing, developing, and curing a resin that is liquid and has photosensitivity as an example. Alternatively, as another method of forming the light shielding layer 18, an inorganic material such as Si, Al, Au, Ag, Cu, Pt, Pd, Al₂O₃, SiO₂, TiO₂, GaN, InGaN, or AlGaN is formed on the light emitting element 13 and the reinforcement resin layer 14, a resin is formed on the inorganic material immediately on the light emitting element 13 by applying a resin having photosensitivity and performing exposure, development, exposure and curing, and thereafter, the inorganic material in the exposed region is formed by wet or dry etching. A region to be exposed depends on the photosensitivity of the resin, and in a case of a negative type, exposure is mainly performed on the region on the reinforcement resin, and in a case of a positive type, the exposure is mainly performed on the region on the light emitting element 13. Since the light shielding layer 18 is formed on the side surfaces of the phosphor layers 15 and 16 in this manner, an adhesion area of the phosphor layers 15 and 16 in the light source device 1 is increased, and thus, peeling of the phosphor layers 15 and 16 is suppressed.

In the light source device 1, by covering the side surfaces of the phosphor layers 15 and 16 with the light shielding layer 18, the following actions and effects can be obtained in addition to peeling and suppression of the phosphor layers 15 and 16. First, light can be prevented from leaking from the side surfaces of the phosphor layers 15 and 16. Second, light having a color difference that is not negligible compared to the light emission from the light emitting surfaces of the phosphor layers 15 and 16 is suppressed to be emitted outward from the side surfaces of the phosphor layers 15 and 16, and occurrence of color unevenness in the entire light emission colors of the light source device 1 can be reduced. Third, when the light shielding layer 18 has a light reflection function, the light that progresses in a side direction of the phosphor layers 15 and 16 is reflected by the light shielding layer 18 toward a light extraction direction of the light source device 1, and further, a light emitting region to the outside is restricted. Thereby, a light emission luminance on the light emitting surfaces of the phosphor layers 15 and 16 increases. Fourth, by dissipating heat generated by the phosphor layers 15 and 16 to the light shielding layer 18, heat dissipation of the phosphor layers 15 and 16 can be enhanced. Fifth, by forming the light shielding effect 18, the light emitting layers of the phosphor layers 15 and 16 can be protected from water or oxygen.

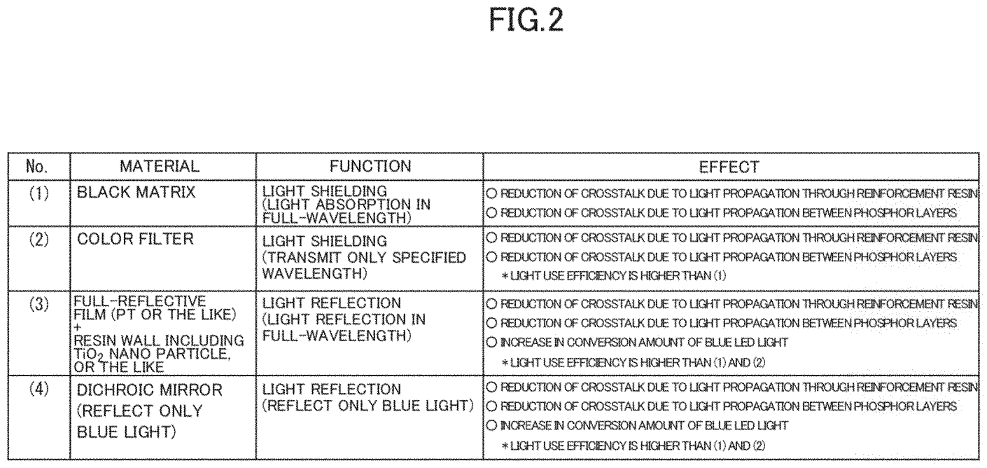

FIG. 2 is an explanatory diagram illustrating a material of the light shielding layer 18 and a function and an effect when the material is used. FIG. 2 illustrates four examples of a black matrix, a color filter, a total reflection film (for example, Pt), and a dichroic mirror as the material of the light shielding layer 18.

### Second Embodiment

Another embodiment of the present invention will be described below. For the sake of convenient description, members having the same functions as the members described in the above embodiment are denoted by the same reference numerals, and description thereof will not be repeated.

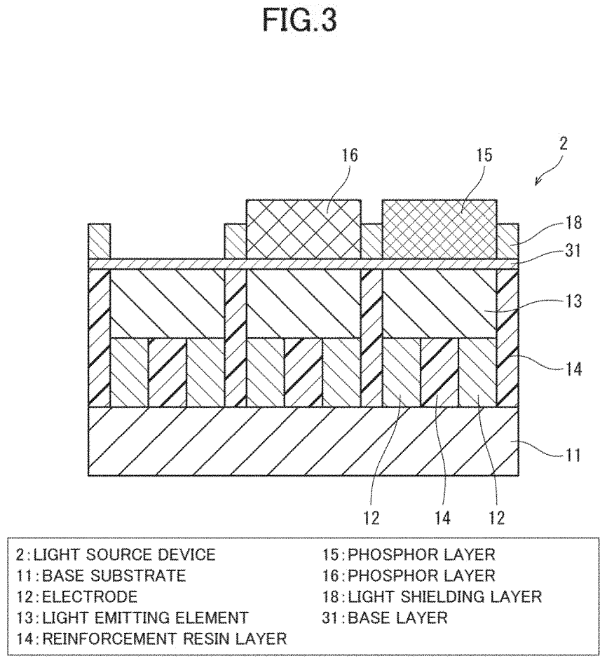

FIG. 3 is a longitudinal cross-sectional diagram illustrating a configuration of a light source device 2 according to the present embodiment. As illustrated in FIG. 3, the light source device 2 includes a base layer 31 in addition to the configuration of the light source device 1 described above. The base layer 31 is provided on the upper surfaces of the three light emitting elements 13 and the reinforcement resin layer 14, that is, between the three light emitting elements 13 and the reinforcement resin layer 14, and the phosphor layers 15 and 16 and the light shielding layer 18.

The base layer 31 is formed of an insulating material having a high adhesive strength to the light emitting element 13 and the phosphor layers 15 and 16 and the light shielding layer 18, and thereby, peeling of the phosphor layers and the light shielding layers can be suppressed. The material is, for example, an organic insulating material such as an acrylic resin or a silicone resin, or an inorganic insulating material such as SiO₂ or Al₂O₃. Alternatively, a configuration in which a plurality of organic insulating materials are stacked or mixed, a configuration in which a plurality of inorganic insulating materials are stacked or mixed, or a configuration in which one or a plurality of organic insulating materials and one or a plurality of inorganic insulating materials are stacked or mixed may be provided or a configuration in which an inorganic insulating material is dispersed in an organic insulating material may be provided. If the layer is configured by a plurality of materials as described above, it is easier to form the base layer 31 having light scattering properties or light shielding properties, and it is also possible to form the base layer 31 having wavelength-selective light scattering properties or light shielding properties. A shape of the layer is not limited as long as the base layer 31 increases an adhesive strength between the light emitting element 13, the phosphor layers 15 and 16, and the light shielding layer 18 and suppresses peeling. If the base layer 31 has a sufficient adhesive strength, it is easy to form the phosphor layers 15 and 16 and the light shielding layer 18 in a target shape if the phosphor layers 15 and 16 are flat. Even if a surface configured by the light emitting element 13 and the reinforcement resin layer 14 is not flat, flattening can be made by the base layer 31 and the phosphor layers 15 and 16 or the light shielding layer 18 can be easily formed. Alternatively, by forming a specified periodic structure such as a rough surface or a concavo-convex surface, a contact area between the phosphor layers 15 and 16, the light shielding layer 18, and the base layer 31 increases, and thus, peeling of the phosphor layers 15 and 16 and the light shielding layer 18 can be suppressed. Furthermore, it is possible to provide optical characteristics such as light scattering properties or light shielding properties as described above, and to increase light extraction efficiency from the light emitting element 13, and in addition to this, if the insulating material has fluidity, the insulating material can be formed by coating and can be formed by sputtering or vapor deposition. A thickness of the base layer 31 is small to be 2 μm or less, preferably 0.5 μm or less, and more preferably 0.1 μm or less. By thus reducing the thickness of the base layer 31, an increase in crosstalk due to formation of the base layer 31 can be suppressed.

The light source device 2 has the following advantages by having the base layer 31.

(1) Adhesion between the phosphor layers 15 and 16 can be enhanced and peeling can be suppressed.

(2) It is possible to suppress transfer of heat generated by the light emitting element 13 to the phosphor layers 15 and 16.

Thereby, it is possible to suppress a decrease in luminous efficiency of the phosphors 15 and 16 whose luminous efficiency decreases due to a temperature increase.

(3) When the light shielding layer 18 include a light reflecting layer formed of a metal such as Si, Al, Au, Ag, Cu, Pt, and Pd, an alloy thereof, or the like, adjacent light emitting elements 13 via the metal light reflection layer can be prevented from being electrically short-circuited (short).

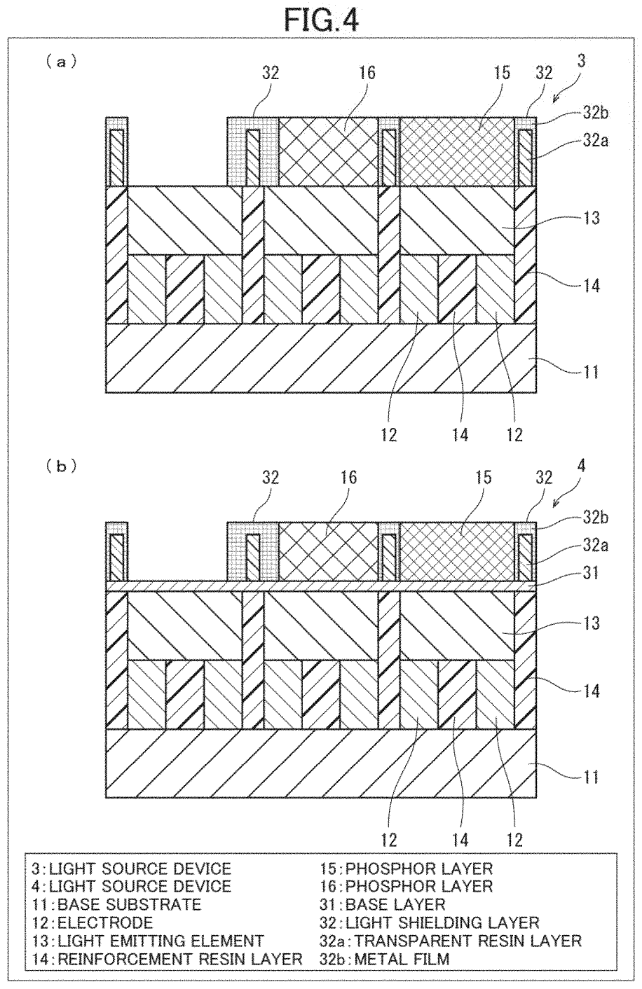

The reason why an advantage of (3) described above is obtained is illustrated in FIGS. 4A and 4B. FIG. 4A is an explanatory diagram when, in the light source device 3 having no base layer 31, the light-emitting elements 13 are short-circuited by a metal light-shielding layer 32 (the light-shielding layer 32 surrounded by a circle) straddling the adjacent light emitting elements 13. FIG. 4B is an explanatory diagram when, in the light source device 4 having the base layer 31 and the light shielding layer 32 illustrated in FIG. 4A, the short-circuit illustrated in FIG. 4A is prevented by the base layer 31. The light shielding layer 32 illustrated in FIGS. 4A and 4B has a configuration in which a transparent resin layer 32a is covered with a metal film 32b. Instead of the transparent resin 32a, the light shielding layer 32 may have a configuration in which inorganic materials such as Si, Al, Au, Ag, Cu, Pt, Pd, Al₂O₃, SiO₂, TiO₂, GaN, InGaN, and AlGaN are covered with the metal film 32b having a light shielding function, and when the light shielding layer 32 is formed of an inorganic material, for example, wet etching or dry etching is used for formation thereof. As described above, the light shielding layer 32 may be configured by a plurality of layers of different materials. For example, when the phosphor layers 15 and 16 are formed of a phosphor and a resin material, it is possible to simultaneously enhance the adhesion between the phosphor layers 15 and 16 and luminance improvement due to a high light reflection performance of the light shielding layer by forming the light shielding layer in order of a transparent resin, a metal film, a transparent resin from the inside.

In a light source device according to another embodiment to be described below, the base layer 31 is not illustrated in particular but may have the base layer 31 like the light source device 2.

### Third Embodiment

Another embodiment of the present invention will be described below. For the sake of convenient description, members having the same functions as the members described in the above embodiment are denoted by the same reference numerals, and description thereof will not be repeated.

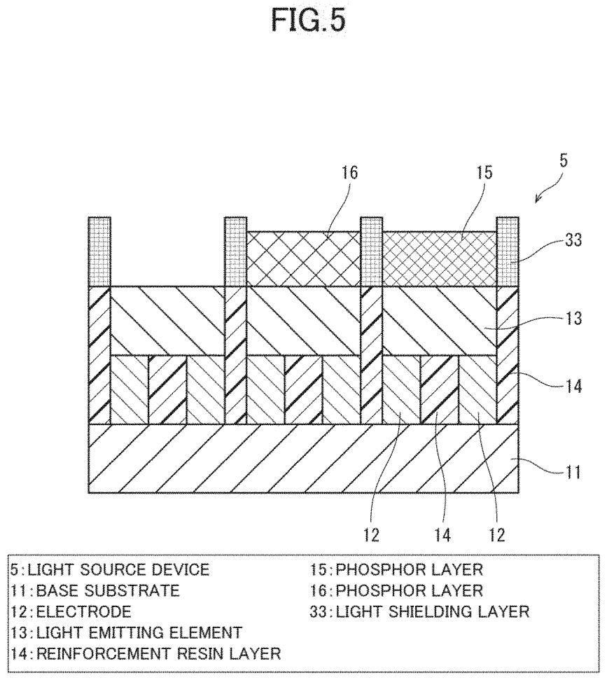

FIG. 5 is a longitudinal cross-sectional diagram illustrating a configuration of a light source device 5 according to the present embodiment. As illustrated in FIG. 5, the light source device 5 includes a light shielding layer 33 instead of the light shielding layer 18 of the light source device 1 illustrated in FIG. 1. Other configurations of the light source device 5 are the same as the configurations of the light source device 1.

In the light source device 5, the light shielding layer 33 is higher than the upper surfaces of the phosphor layers 15 and 16. The light shielding layer 33 may have the same height as the upper surfaces of the phosphor layers 15 and 16. The light shielding layer 33 is formed of a color filter that does not transmit blue light therethrough. The color filter is formed of, for example, a resist resin, a dispersant, and an organic pigment. Alternatively, a light shielding layer 33 may have a configuration in which a resin layer is configured by a full-wavelength reflection film.

Since the light source device 5 includes the light shielding layer 33 as described above, it is possible to suppress a light guide from an inside of the reinforcement resin layer 14 or side surfaces of the phosphor layers 15 and 16. Other functions and effects of the light source device 5 are the same as the functions and effects of the light source device 1 described above.

### Fourth Embodiment

Another embodiment of the present invention will be described below. For the sake of convenient description, members having the same functions as the members described in the above embodiment are denoted by the same reference numerals, and description thereof will not be repeated.

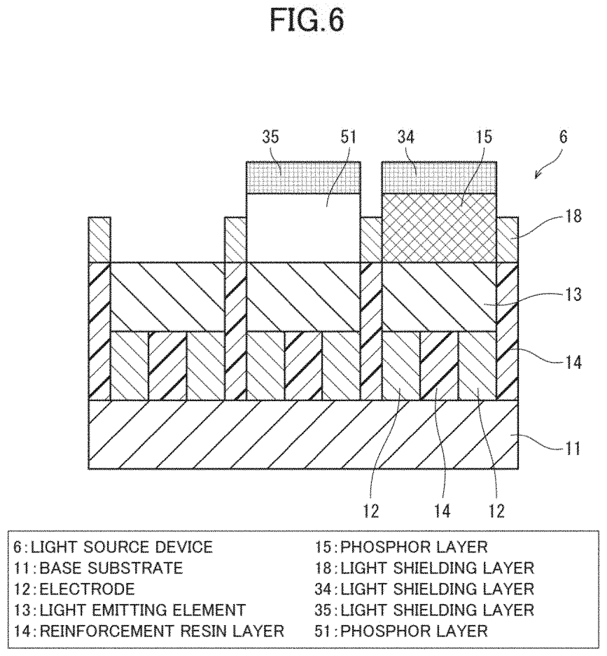

FIG. 6 is a longitudinal cross-sectional diagram illustrating a configuration of a light source device 6 according to the present embodiment. As illustrated in FIG. 6, the light source device 6 is different from the light source device 1 illustrated in FIG. 1 in that a yellow phosphor layer 51 is provided on the light emitting element 13 in the center instead of the green phosphor layer 16. The light source device 6 includes light shielding layers 34 and 35 (second light shielding layers) on the phosphor layers 15 and 51, respectively, in addition to the light shielding layer 18 (first light shielding layer) of the light source device 1. The light shielding layer 34 on the red phosphor layer 15 is formed of a color filter that transmits red light therethrough, and the light shielding layer 35 on the yellow phosphor layer 51 is formed of a color filter that transmits green light therethrough. Other configurations of the light source device 6 are the same as the configurations of the light source device 1.

When an adhesive strength between the phosphor layers 15 and 51 and the light emitting element 13 or the light shielding layer 18, or an adhesive strength between the phosphor layers and the base layer as in the second embodiment is weak and the phosphor layers 15 and 51 are easily peeled off, the light shielding layers 34 and 35 are formed of a material having high adhesion between the phosphor layers 15 and 51 and the light shielding layer 18, and the light shielding layers 34 and 35 are formed to straddle the phosphor layers and the light shielding layers 18 on both sides thereof, and thus, it is possible to make the phosphor layers 15 and 51 difficult to be peeled off. One or both of another organic material and an inorganic material are formed between the light shielding layer 18, the light shielding layers 34 and 35, and the phosphor layers 15 and 51, and thus, it is also possible to further form a layer (insertion layer) having high adhesion on the phosphor layers 15 and 51, the shielding layer 18, and the light shielding layers 34 and 35. By appropriately controlling roughness of a surface on a light shielding layer side of an insertion layer or a concavo-convex shape, it is possible to increase a contact area or to make the light shielding layers 34 and 35 difficult to be peeled off, and it is also possible to enhance light extraction from the phosphor layers 15 and 51. In order to suppress crosstalk between the sub-pixels, a thickness of the insertion layer is small to be 2 μm or less, preferably 0.5 μm or less, more preferably 0.1 μm or less. Although the insertion layer is not described in other embodiments, the same applies to other embodiments as well, and the insertion layer adopts a material having a high affinity for a configuration material in contact with the insertion layer, and thereby, it is possible to suppress peeling of each layer including the phosphor layers and configuration materials from the light source device.

In the light source device 6, by selecting a color filter according to the purpose, chromaticity of the light source device 6 can be controlled by light absorption characteristics of the color filter. For example, if light absorption efficiencies of the phosphor layers 15 and 51 are low, or if thicknesses of the phosphor layers 15 and 51 are insufficient, it is considered that light emission of the light emitting element 13 by the phosphor layers 15 and 51 is not sufficiently absorbed, light emission components of the light emitting element 13 and light emission components of a phosphor will be mixed, and the chromaticity is not sufficient. In this case, as in the present embodiment, a color filter having characteristics of absorbing the light emission components of the light emitting element 13 and transmitting the light emission components of the phosphor therethrough is formed as the light shielding layers 34 and 35 on a color conversion layer, and thus, a color reproduction range of the light source device 6 can be increased. By forming the color filter in the phosphor layer that absorbs a part of the light emission components of the phosphor, it is possible to increase color purity of light emitted from each sub-pixel and to further expand the color reproduction range. For example, in order to improve the color reproduction range, it is preferable to form a color filter in which light transmittance in a wavelength range of 420 nm or more and 460 nm or less is 10% or less, and a maximum light transmittance in the wavelength range of 510 nm or more and 580 nm or less is 50% or more, on the phosphor layer 51 serving as a green pixel. It is preferable to form a certain color filter in which the light transmittance in the wavelength range of 420 nm or more and 460 nm or less is 10% or less and the maximum light transmittance in the wavelength range of 600 nm or more and 800 nm or less is 50% or more, on the phosphor layer 15 serving as a red pixel.

When the color reproduction range is not intended to increase, it is appropriate to use a color filter having a high light transmittance and a narrow wavelength range in a visible light region. For example, a color filter having light transmittance of 10% or less in a wavelength range of 420 nm or more and 460 nm or less, and maximum light transmittance of 50% or more in a wavelength range of 510 nm or more and 560 nm or less is formed on a phosphor layer serving as a green pixel, and a color filter having light transmittance of 10% or less in a wavelength range of 420 nm or more and 480 nm or less and maximum light transmittance of 50% or more in a wavelength range of 620 nm or more and 800 nm or less is formed on the phosphor layer serving as a red pixel. Meanwhile, when brightness is prioritized more than the color reproduction range, a color filter having a wide wavelength range and high light transmittance in the visible light region is used, or a color filter having low light transmittance in a wavelength range with low visibility.

### Fifth Embodiment

Another embodiment of the present invention will be described below. For the sake of convenient description, members having the same functions as the members described in the above embodiment are denoted by the same reference numerals, and description thereof will not be repeated.

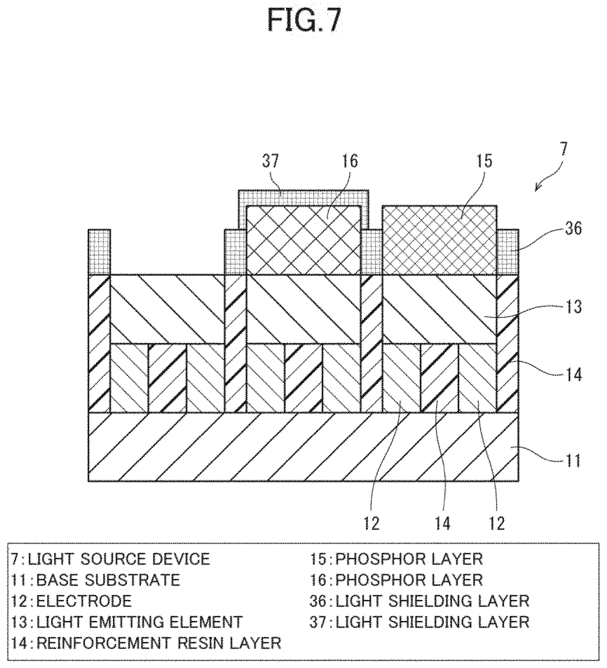

FIG. 7 is a longitudinal cross-sectional diagram illustrating a configuration of a light source device 7 according to the present embodiment. As illustrated in FIG. 7, the light source device 7 includes light shielding layers 36 and 37 instead of the light shielding layer 18 of the light source device 1 illustrated in FIG. 1. The light shielding layer 36 covers the phosphor layers 15 and 16 from a lower end portion to the middle of a side surface thereof like the light shielding layer 18. In addition, the light shielding layer 37 covers the phosphor layer 16 on the light emitting element 13 in the central part from the middle of the side surface to an upper end portion and an upper surface. As described above, by forming the light shielding layer 37 so as to straddle the phosphor layer 16 and the light shielding layers 36 on both sides thereof, the phosphor layer 16 can be hardly peeled off.

The light shielding layers 36 and 37 are formed of color filters that transmit green light therethrough. The light shielding layer 37 has a hardened upper surface of the phosphor layer 16, and thus, a light shielding layer of full-wavelength reflection is impossible. In the present embodiment, since all sides of a phosphor layer are covered with color filters, it is possible to suppress emission of unnecessary wavelength components included in light emission from the phosphor layer, and thus, a color reproduction range can be increased.

### Sixth Embodiment

Another embodiment of the present invention will be described below. For the sake of convenient description, members having the same functions as the members described in the above embodiment are denoted by the same reference numerals, and description thereof will not be repeated.

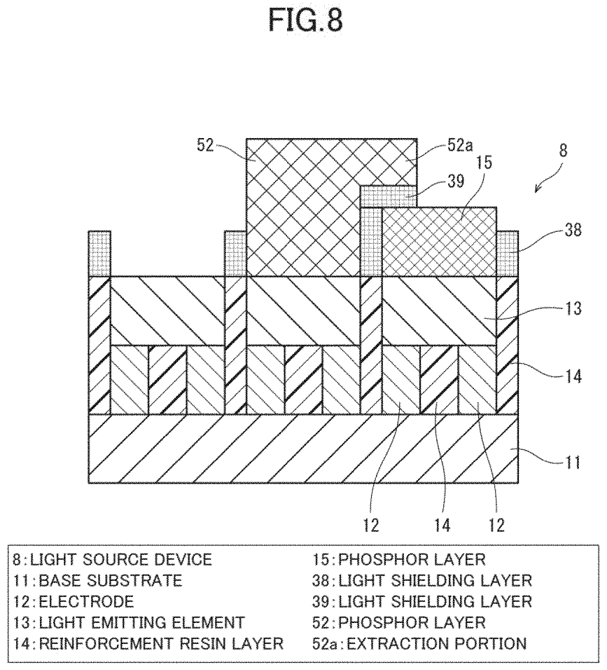

FIG. 8 is a longitudinal cross-sectional diagram illustrating a configuration of a light source device 8 according to the present embodiment. As illustrated in FIG. 8, the light source device 8 includes light shielding layers 38 and 39 instead of the light shielding layer 18 of the light source device 1 illustrated in FIG. 1. The light source device 8 includes a green phosphor layer 52 instead of the green phosphor layer 16 on the light emitting element 13 in the center of the light source device 1.

The phosphor layer 52 is larger in surface area than the phosphor layer 15 and includes an extruded portion 52a whose upper portion protrudes to a part of an upper surface of the phosphor layer 15. The green phosphor layer 52 is thickened and widened by the shape. By increasing roughness of a surface, an adhesion area of the surface increases, and the phosphor layer 15 and the phosphor layer 16 are hardly peeled off.

The light shielding layers 38 and 39 are formed of a full-wavelength reflection film. The light shielding layer 38 covers the phosphor layers 15 and 52 from a lower end portion to the middle thereof in the same manner as the light shielding layer 18. The light source device 38 between the phosphor layers 15 and 52 covers the phosphor layer 15 from the lower end portion to an upper end portion of the side surface thereof. The light shielding layer 39 covers a lower surface of a protrusion portion 52a of the phosphor layer 52 and a part of an upper surface of the phosphor layer 15, which is a portion below the protrusion portion 52a. It is impossible for the light shielding layer 39 to cover the entire upper surface of the phosphor layer 15 from the full-wavelength reflection film because red light cannot be extracted from the phosphor layer 15. Since color conversion capability of a phosphor layer depends on characteristics and a thickness of a material, even when color conversion characteristics of a material of the phosphor layer 52 are low, the phosphor layer 52 can be formed thick in the present embodiment and a color reproduction range of a light source device can be increased.

### Seventh Embodiment

Another embodiment of the present invention will be described below. For the sake of convenient description, members having the same functions as the members described in the above embodiment are denoted by the same reference numerals, and description thereof will not be repeated.

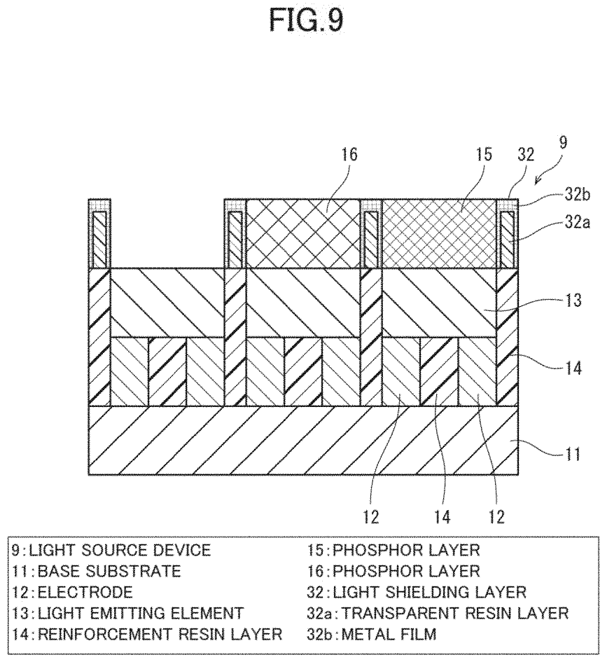

FIG. 9 is a longitudinal cross-sectional diagram illustrating a configuration of a light source device 9 according to the present embodiment. As illustrated in FIG. 9, the light source device 9 includes a light shielding layer 32 instead of the light shielding layer 18 of the light source device 1 illustrated in FIG. 1. The light shielding layer 32 has a configuration in which a transparent resin layer 32a is covered with a metal film 32b, and has a height substantially equal to an upper surfaces of the phosphor layers 15 and 16. By making the light shielding layer 32 and the phosphor layers 15 and 16 have substantially the same height, an adhesion area between the light shielding layer 32 and the phosphor layers 15 and 16 can be maximized, and the phosphor layer 15 and the phosphor layer 16 are hardly peeled off. The light shielding layer 32 has a light reflecting function because the transparent resin layer 32a is covered with the metal film 32b. Other configurations of the light source device 9 are the same as the configurations of the light source device 1. The light shielding layer 32 may have a configuration in which the metal film 32b covers an inorganic material such as Si, Al, Au, Ag, Cu, Pt, Pd, Al₂O₃, SiO₂, TiO₂, GaN, InGaN, or AlGaN instead of the transparent resin 32a, and when the light shielding layer 32 is formed of an inorganic material, for example, wet etching or dry etching is used for formation of the light shielding layer. The light source device 9 has the same functions and effects as the configurations of the light source device 1 described above. For example, it is generally difficult to form a light shielding layer formed of only a metal with a thickness of several μm, and depending on a size of a pixel, it is easy to form a metal film on a structure formed of a resin as in the present embodiment. An example of a method of manufacturing the light source device 9 according to the present embodiment will be described below.

### Eighth Embodiment

Another embodiment of the present invention will be described below. For the sake of convenient description, members having the same functions as the members described in the above embodiment are denoted by the same reference numerals, and description thereof will not be repeated.

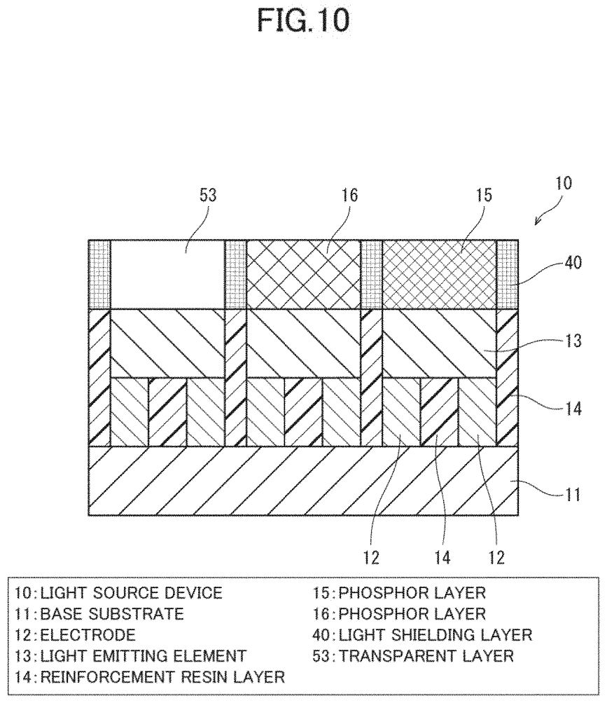

FIG. 10 is a longitudinal cross-sectional diagram illustrating a configuration of a light source device 10 according to the present embodiment. As illustrated in FIG. 10, the light source device 10 includes a light shielding layer 40 instead of the light shielding layer 18 of the light source device 1 illustrated in FIG. 1. The light shielding layer 40 is formed of, for example, a color filter that does not transmit blue light therethrough and has the same height as the upper surfaces of the phosphor layers 15 and 16. By making a resin material forming the light shielding layer 40 and a resin material forming the phosphor layer 15 the same, or by using a resin material having a high affinity even in a different resin material, adhesion between the light shielding layer 40 and the phosphor layers 15 and 16 is increased, and thus, the phosphor layer 15 and the phosphor layer 16 are hardly peeled off. In addition, by making the light shielding layer 40 and the phosphor layers 15, 16 substantially the same height, an adhesion area between the light shielding layer 40 and the phosphor layers 15 and 16 can be maximized, and thus, the phosphor layer 15 and the phosphor layer 16 are hardly peeled off.

In the light source device 10, a transparent layer 53 is provided on the upper surface of the light emitting element 13 other than the light emitting element 13 having the phosphor layers 15 and 16 on the upper surface. The transparent layer 53 is formed of a resin containing no phosphor.

As described above, the light source device 10 includes the phosphor layers 15 and 16 provided on two light emitting elements 13 among the three light emitting elements 13, and the transparent layer 53 is provided on the remaining one light emitting element 13, and thus, alignment characteristics of each color can be uniformly aligned. Other functions and effects of the light source device 10 are the same as the functions and effects of the light source device 1 described above.

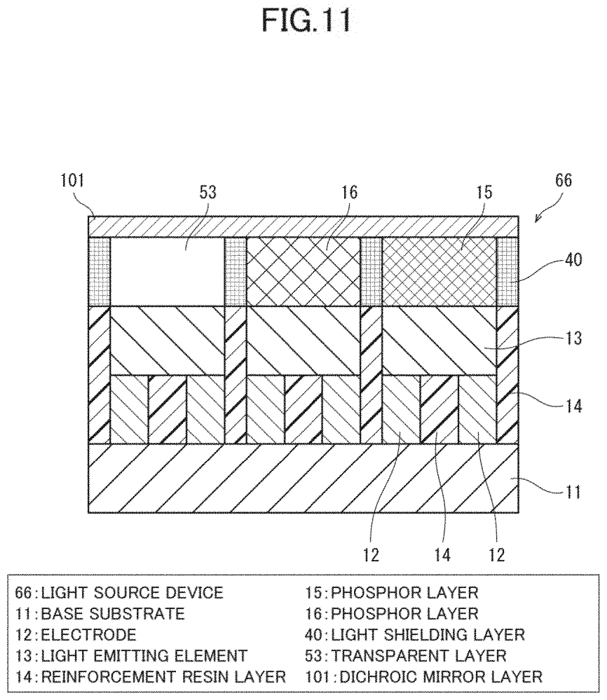

FIG. 11 is a longitudinal cross-sectional diagram illustrating a configuration of a light source device 66 according to a modification example of the light source device 10 illustrated in FIG. 10 The light source device 66 illustrated in FIG. 11 includes a dichroic mirror layer 101 on the phosphor layers 15 and 16, the transparent layer 53, and the light shielding layer 40. By forming the dichroic mirror layer 101 so as to straddle the phosphor layers 15 and 16 and the light shielding layer 40, the phosphor layer 15 and the phosphor layer 16 are hardly peeled off. In addition, in the light source device 66, the dichroic mirror layer 101 exists even when blue light cannot be absorbed only by the phosphor layers 15 and 16 serving as the red sub-pixel and the green sub-pixel, and thereby, an optical path length of the blue light is lengthened, and absorption of the blue light by the phosphor layers 15 and 16 is increased. Thereby, a color reproduction range can be increased. In addition, the phosphor has characteristics of absorbing a part of light emission thereof, which is generally called self-absorption, and by thickening the phosphor layers 15 and 16 or by increasing concentration of phosphors of the phosphor layers 15 and 16, a light emission efficiency decreases or a shift to a long wavelength side of a light emission peak wavelength is performed. Meanwhile, in order to increase the color reproduction range, it is necessary to suppress emission of the blue light from the light emitting element 13, and it is desirable to increase thicknesses of the phosphor layers 15 and 16 as much as possible or to increase concentration of phosphors in the layers 15 and 16. That is, there is a trade-off between the color reproduction range and the efficiency only in the phosphor layers 15 and 16. Therefore, by forming a color filter that reflects only the blue light from the light emitting element 13 or the dichroic mirror 101 that reflects only the blue light from the light emitting element 13, the color reproduction range can be increased and a phosphor emission efficiency can be increased.

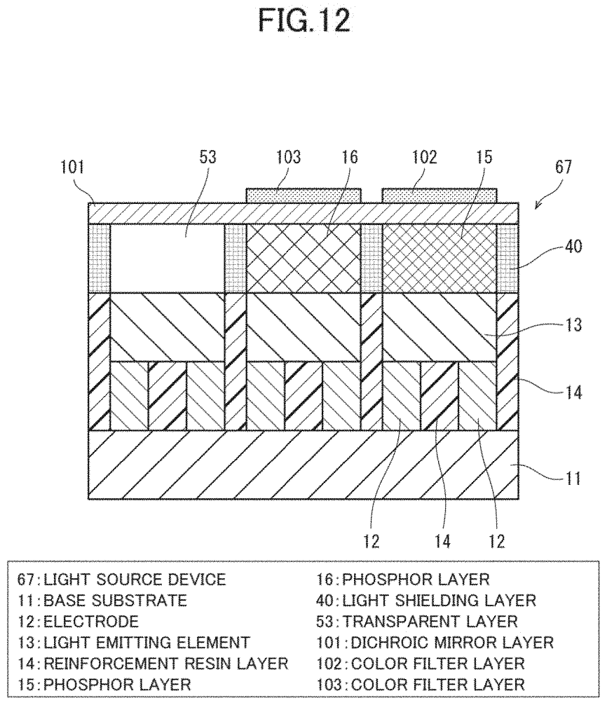

FIG. 12 is a longitudinal cross-sectional diagram illustrating a configuration of a light source device 67 according to another modification example of the light source device 10 illustrated in FIG. 10. The light source device 67 illustrated in FIG. 12 includes a red color filter layer 102 on the dichroic mirror layer 101 and the red phosphor layer 15, and includes a green color filter layer 101 on the dichroic mirror layer 101 and a green phosphor layer 16. By forming the dichroic mirror layer 101 so as to straddle the phosphor layers 15 and 16 and the light shielding layer 40, the phosphor layer 15 and the phosphor layer 16 are hardly peeled off. In addition, the light source device 67 can further increase a color reproduction range.

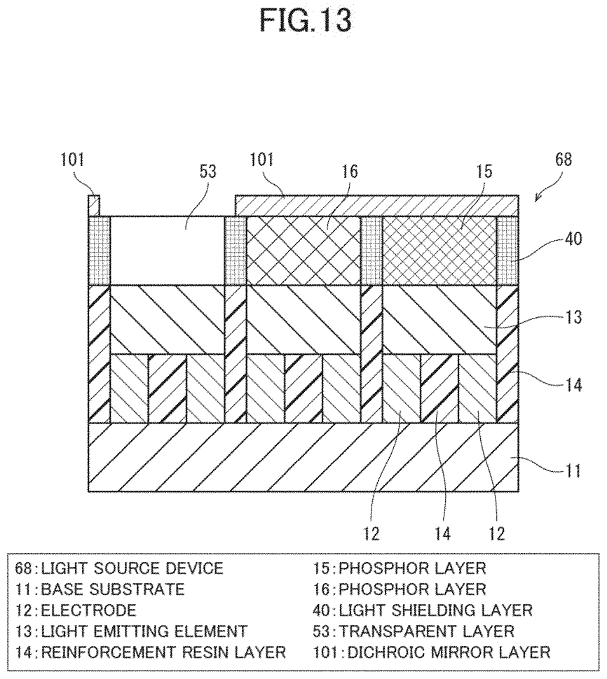

FIG. 13 is a longitudinal cross-sectional diagram illustrating a configuration of a light source device 68 according to still another modification example of the light source device 10 illustrated in FIG. 10. The light source device 68 illustrated in FIG. 13 differs from the light source device 66 illustrated in FIG. 11 in that the dichroic mirror layer 101 is not provided on the transparent layer 53. Actions and effects of the light source device 68 are the same as the actions and effects of the light source device 66 described above.

### Ninth Embodiment

Another embodiment of the present invention will be described below. For the sake of convenient description, members having the same functions as the members described in the above embodiment are denoted by the same reference numerals, and description thereof will not be repeated.

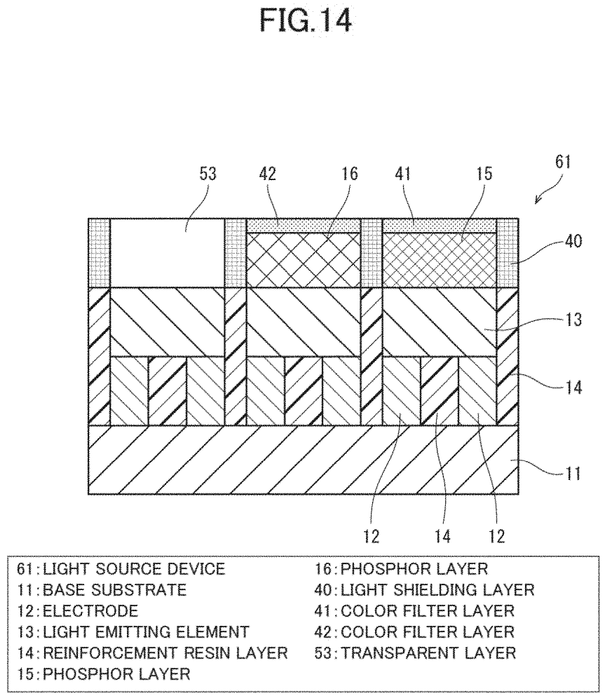

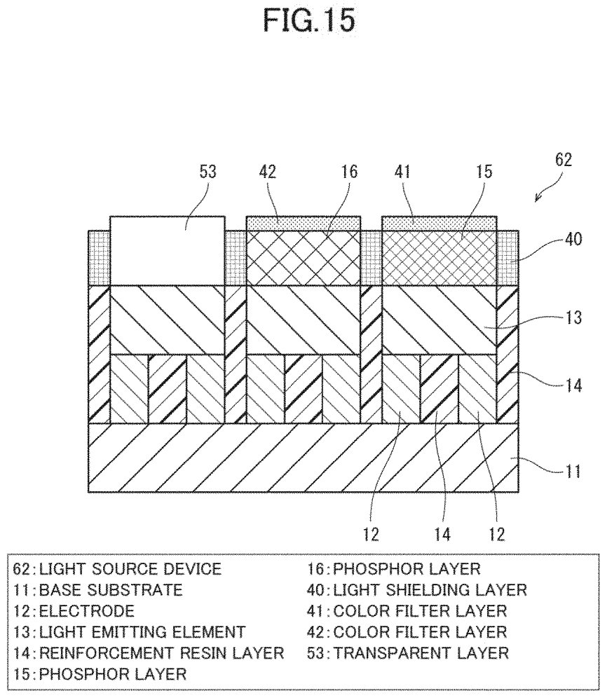

FIG. 14 is a longitudinal cross-sectional diagram illustrating a configuration of a light source device 61 according to the present embodiment. FIG. 15 is a longitudinal cross-sectional diagram illustrating a configuration of a light source device 62 according to a modification example of the light source device 61 illustrated in FIG. 14. As illustrated in FIG. 14, the light source device 61 includes the light shielding layer 40 like the light source device 10 instead of the light shielding layer 18 of the light source device 1 illustrated in FIG. 1.

The light source device 61, unlike the light source device 10, includes a color filter layer 41 that transmits red light therethrough on the red phosphor layer 15 and includes a color filter layer 42 that transmits green light therethrough on the green phosphor layer 16. Heights of upper surfaces of the color filter layers 41 and 42 are substantially the same as the height of the upper surface of the light shielding layer 40. Therefore, the heights of the upper surfaces of the phosphor layers 15 and 16 are lower than the height of the upper surface of the light shielding layer 40. By forming the color filter layers 41 and 42 so as to be in contact with both the phosphor layers 15 and 16 and the light shielding layer 40, the phosphor layer 15 and the phosphor layer 16 are hardly peeled off.

The light source device 61 may have a configuration in which the height of the light shielding layer 40 is the same as the height of the upper surfaces of the phosphor layers 15 and 16. A light source device having such a configuration is illustrated as a light source device 62 in FIG. 15. By forming the light shielding layer 40 and the color filter layers 41 and 42 in this manner, a thickness of a color filter covering the phosphor layers 15 and 16 is increased as compared with the fifth embodiment, and thus, a color reproduction range is easily increased.

The color filter layers 41 and 42 may be dichroic mirrors that selectively reflect a blue wavelength instead of the color filter material. By using a dichroic mirror, all the light emitted from the phosphor is extracted and the light emitted from the light emitting element is reflected, and thus, both an increase of a color reproduction range and an increase in color conversion capability can be simultaneously achieved.

### First Example

Hereinafter, an example of the light source device 61 will be described together with an effect of providing the light shielding layer 40. The above-described effects are also illustrated in FIG. 27.

With the configuration of the light source device 61 described above, the light source device 61 was manufactured which includes the light shielding layer 40 having a width of 1 μm and a thickness of 1 μm and the light emitting element 13 having a size of 8 μm×24 μm by using a color filter material that absorbs blue light from the light emitting element 13. When only pixels corresponding to each color were lit, CIE1931 color coordinate values were measured and a color gamut area was calculated. When only the green pixel was lit, x=0.620/y=0.308, when only the red pixel was lit, x=0.208/y=0.645, and when only the blue pixel was lit, x=0.146/y=0.040. The color gamut area ratio was 63.7% for BT2020, 85.3% for NTSC, and 120.5% for sRGB.

Subsequently, a light source device having the same configuration as the light source device 61 except that the light shielding layer 40 was not provided was manufactured, and when only the pixels corresponding to each color were lit, the CIE1931 color coordinate values were measured, and the color gamut area was calculated. When only the red pixel was lit, x=0.257/y=0.162, when only the green pixel was lit, x=0.213/y=0.255, and when only the blue pixel was lit, x=0.158/y=0.063. A color gamut area ratio was 3.2% for BT2020, 4.3% for NTSC, and 6.0% for sRGB.

Thus, it can be seen that formation of the light shielding layer 40 increases a color reproduction range of the light source device 61.

### Tenth Embodiment

Another embodiment of the present invention will be described below. For the sake of convenient description, members having the same functions as the members described in the above embodiment are denoted by the same reference numerals, and description thereof will not be repeated.

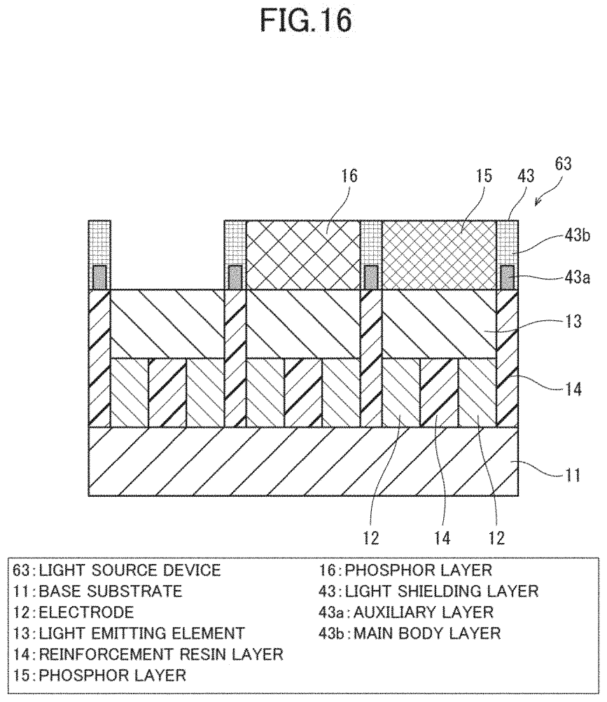

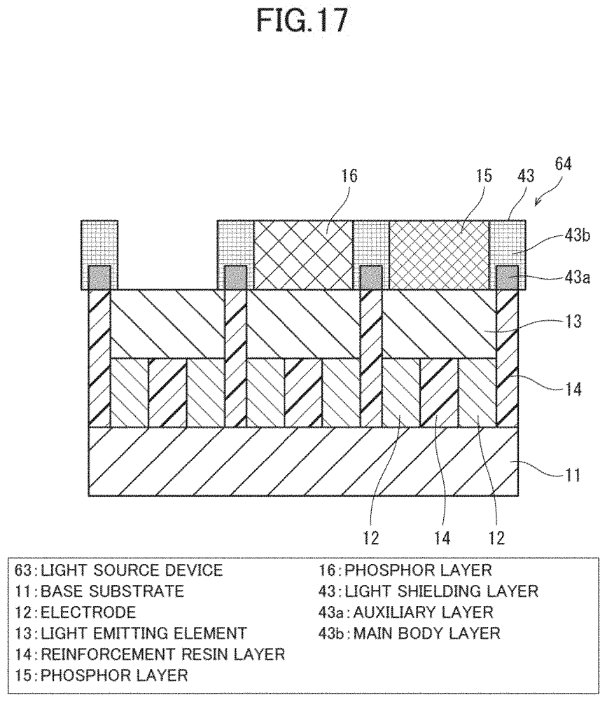

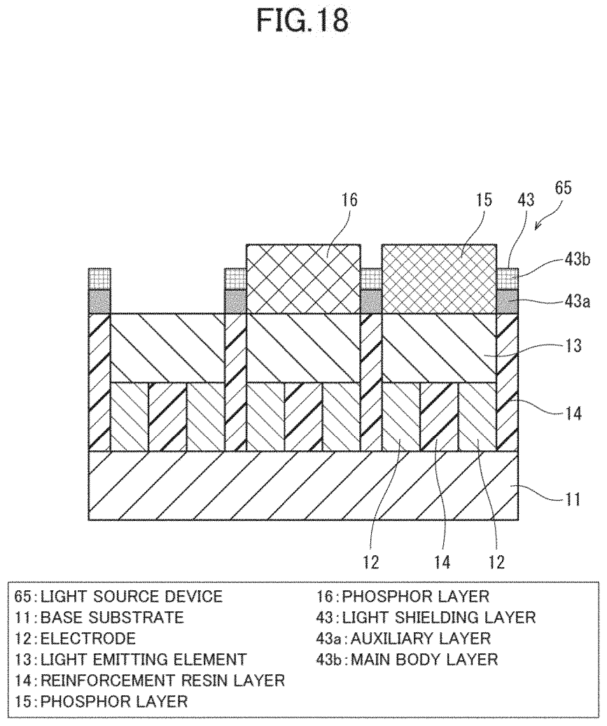

FIG. 16 is a longitudinal cross-sectional diagram illustrating a configuration of the light source device 63 according to the present embodiment. FIG. 17 is a longitudinal cross-sectional diagram illustrating a configuration of a light source device 64 according to a modification example of the light source device 63 illustrated in FIG. 16. FIG. 18 is a longitudinal cross-sectional diagram illustrating a configuration of a light source device 65 according to another modification example of the light source device 63 illustrated in FIG. 16.

As illustrated in FIG. 16, the light source device 63 includes a light shielding layer 43 instead of the light shielding layer 18 of the light source device 1 illustrated in FIG. 1. In the present embodiment, a height of the light shielding layer 43 is the same as the height of the upper surfaces of the phosphor layers 15 and 16. The light shielding layer 43 includes an auxiliary layer 43a and a main body layer 43b.

The auxiliary layer 43a is provided on an upper surface of the reinforcement resin layer 14, and a width of a lower surface is smaller than the width of the upper surface of the reinforcement resin layer 14. The auxiliary layer 43a is a phosphor layer formed of, for example, a red phosphor. The main body layer 43b is provided so as to cover a side surface and an upper surface of the auxiliary layer 43a except for a lower surface of the auxiliary layer 43a. The main body layer 43b is formed of a light shielding member, for example, a color filter. In the light shielding layer 43, a width of the auxiliary layer 43a<a width of the main body layer 43b=a width of the reinforcement resin layer 14.

Adhesion of the auxiliary layer 43a to the reinforcement resin layer 14 is good. Therefore, even when the adhesion of the main body layer 43b with respect to the reinforcement resin layer 14 is low, the light source device 63 can provide the light shielding layer 43 having high adhesion onto the reinforcement resin layer 14 for the reinforcement resin layer 14.

A relationship between the width of the auxiliary layer 43a, the width of the reinforcement resin layer 14, and the width of the main body layer 43b is not limited to the above-described relationship, and the width of the auxiliary layer 43a may be smaller than the width of the reinforcement resin layer 14 or may be the same. The width of the auxiliary layer 43a needs to be equal to the width of the reinforcement resin layer 14.

For example, in the light source device 64 illustrated in FIG. 17, the width of the auxiliary layer 43a=the width of the reinforcement resin layer 14<the width of the main body layer 43b. In the light source device 65 illustrated in FIG. 18, the main body layer 43b is provided to cover only the upper surface of the auxiliary layer 43a, and the width of the auxiliary layer 43a=the width of the reinforcement resin layer 14=the width of the main body layer 43b.

[First Method of Manufacturing Light Source Device]

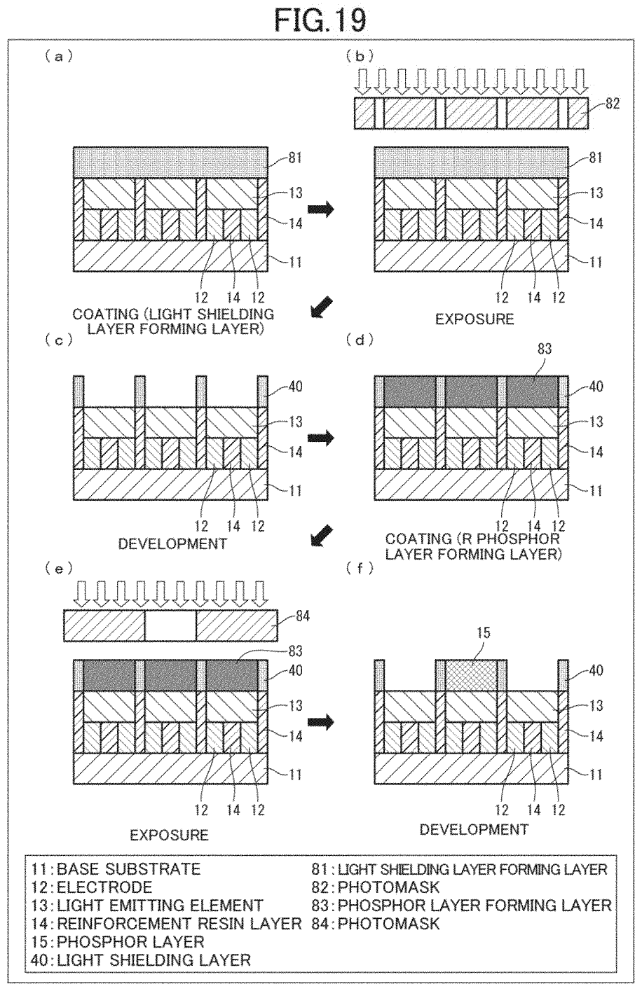

A method of manufacturing the light source device according to the present embodiment will be described. FIG. 19 is a longitudinal cross-sectional diagram illustrating a method of manufacturing the light source device according to the present embodiment. FIG. 19 corresponds to, for example, the method of manufacturing the light source device 10 illustrated in FIG. 10 and illustrates an example of a case where positions of the phosphor layers 15 and 16 are reversed with respect to the light source device 10.

First, as illustrated in (a) of FIG. 19, a state is provided in which the electrodes 12, the light emitting elements 13, and the reinforcement resin layers 14 are provided on the base substrate 11. After the light emitting elements 13 are bonded to the base substrate 11 via the electrodes 12, reinforcement resins are filled between the base substrate and the light emitting elements to obtain a state illustrated in (a) of FIG. 19. Alternatively, an inorganic reinforcement layer formed of an inorganic material such as si, Al, Au, Ag, Cu, Pt, Pd, Al₂O₃, SiO₂, TiO₂, GaN, InGaN, or AlGaN instead of the reinforcement resin is formed previously on the base substrate 11 or on a side surface of the sub-pixels of the light emitting element 13, and the base substrate 11 and the light emitting element 13 are bonded to each other via the electrode 12, and thereby, a state illustrated in (a) of FIG. 19 can be obtained. At this time, the light emitting elements 13 are formed in an array or more in a growth substrate shape of sapphire, GaN, Si or the like, and after being bonded to the base substrate, a growth substrate can be peeled off by laser (for example, ultraviolet laser) irradiation, grinding, polishing, or the like. Alternatively, the individual light emitting elements can be sequentially bonded to the base substrate. In addition, after emphasizing the reinforcement resin or after peeling the growth substrate, a surface of the light emitting element can be flattened by grinding, polishing, or the like, or the surface of the light emitting element can be formed without absorption or residue of an unnecessary material.

Next, a forming layer of light shielding layer 81 is formed by applying, for example, a light shielding layer material for forming the light shielding layer 40 onto the entire upper surface of the three light emitting elements 13 and the reinforcement resin layers 14. In the figure, the light emitting element is configured by three sub-pixels respectively corresponding to red, green, and blue, but the light emitting elements are originally light emitting elements having an array shape of m rows and n columns (m and n are integers of 2 or more). Next, the forming layer of light shielding layer 81 is subjected to an exposure step using a photomask 82 illustrated in (b) of FIG. 19 and a development step illustrated in (c) of FIG. 19 to form the light-shielding layer 40, and next, as illustrated in (d) of FIG. 19, upper surfaces of the three light emitting elements 13 are coated with a red phosphor layer material for forming the phosphor layer 15 to form a forming layer of phosphor layer 83 (phosphor layer material coating step).

Next, the forming layer of phosphor layer 83 is subjected to an exposure step using a photomask 84 illustrated in (e) of FIG. 19 and a development step illustrated in (f) of FIG. 19 to form a red phosphor layer 15 on the light emitting element 13 in a central portion.

Thereafter, by repeating the same steps as the phosphor layer material coating step, the exposure step and the development step illustrated in (d) to (f) of FIG. 19, the green phosphor layer 16 and the transparent layer 53 are formed on the upper surface of the light emitting element 13 next to the light emitting element 13 on which the red phosphor layer 15 is formed.

Likewise, a color filter layer can be formed on the upper surface of the phosphor by repeating the same steps as the coating step, the exposure step, and the development step illustrated in (d) to (f) of FIG. 19. By making an exposure width larger than a width of a phosphor layer, it is also possible to form the color filter layer on a side surface of the phosphor layer simultaneously with the upper surface of the phosphor layer. Alternatively, by repeating the same steps as the coating step, the exposure step, and the development step illustrated in (a) to (c) of FIG. 19, a light shielding layer is formed at the same place between the phosphor layers, and a light shielding layer having a higher height can be provided between the phosphor layers.

In each step of the present manufacturing method, baking is performed at an appropriate temperature and time after application, after exposure, and after development, if necessary. Although the base layer 31 is not illustrated in the present embodiment, the base layer may be formed on the base substrate 11 as described in the second embodiment.

Although not illustrated in the drawing, the light shielding layer 18, as described in the first embodiment, may be formed by forming an inorganic material such as Si, Al, Au, Ag, Cu, Pt, Pd, Al₂O₃, SiO₂, TiO₂, GaN, InGaN, or AlGaN on the light emitting element 13 and the reinforcement resin layer 14, coating with a photosensitive resin, and performing exposure, development, exposure, and curing, and thereafter, by forming a resin on the inorganic material directly on the light emitting element, and by performing wet or dry etching of the inorganic material in the exposed region as another formation method. A region to be exposed depends on photosensitivity of the resin, in a case of a negative type, the exposure is mainly performed on the region on a reinforcement resin, and in a case of a positive type, the exposure is mainly performed on the region on the light emitting element.

[Second Method of Manufacturing Light Source Device]

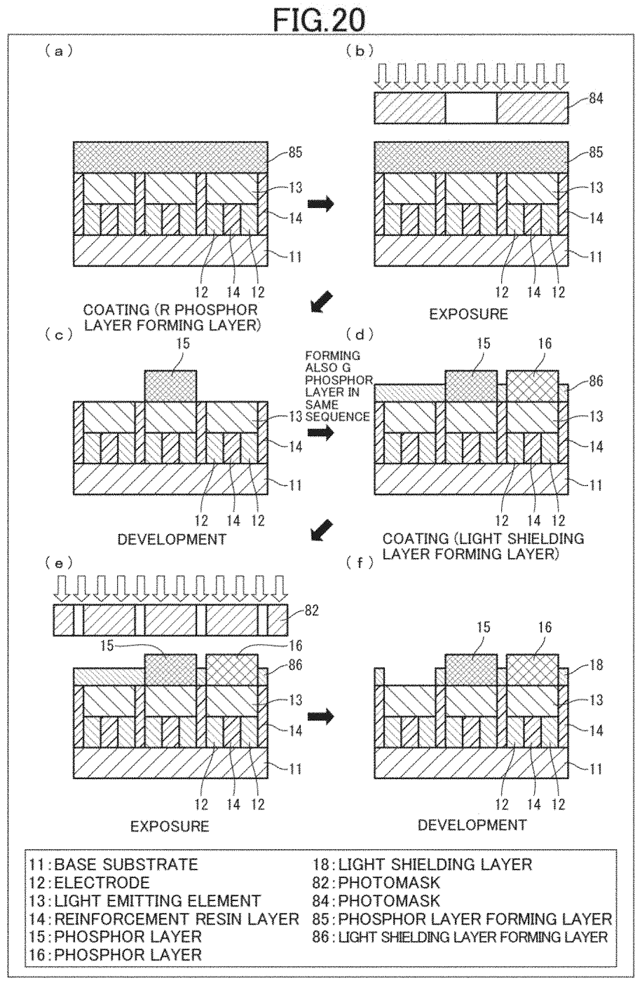

Another method of manufacturing the light source device according to the present embodiment will be described. FIG. 20 is a longitudinal cross-sectional diagram illustrating another method of manufacturing the light source device according to the present embodiment. FIG. 20 corresponds to, for example, the method of manufacturing the light source device 1 illustrated in FIG. 1 and illustrates an example of a case where positions of the phosphor layers 15 and 16 are reversed with respect to the light source device 1.

First, as illustrated in (a) of FIG. 20, a state is provided in which the electrodes 12, the light emitting elements 13, and reinforcement resin layers 14 are provided on the base substrate 11. Next, the entire upper surface of the three light emitting elements 13 and the reinforcement resin layers 14 are coated with a red phosphor layer material to form a forming layer of phosphor layer 85 (phosphor layer material coating step).

Next, a red phosphor layer 15 is formed on the light emitting element 13 in a central portion through an exposure step for the forming layer of phosphor layer 85 using a photomask 84 illustrated in (b) of FIG. 20 and a development step illustrated in (c) of FIG. 20.

Thereafter, a green phosphor layer 16 is formed on the upper surface of the light emitting element 13 adjacent to the light emitting element 13 on which the red phosphor layer 15 is formed, through the phosphor layer material coating step, the exposure step, and the developing step described above.

Next, as illustrated in (d) of FIG. 20, in order to form the light shielding layer 18, the forming layer of light shielding layer 86 is formed by being coated with a light shielding layer material on the entire surface of the upper surfaces of the three light emitting elements 13 and the upper surfaces of the reinforcement resin layer 14 where the phosphor layers 15 and 16 do not exist (phosphor layer coating step).

Next, in each step of the present manufacturing method in which the light shielding layer 18 is formed through an exposure step using a photomask 82 illustrated in (e) of FIG. 20 and a development step illustrated in (f) of FIG. 20, baking is performed at an appropriate temperature and time after coating, after exposure, and after development, if necessary, for the forming layer of light shielding layer 86. Although the base layer 31 is not illustrated in the present embodiment, the base layer may be formed on the base substrate 11 as described in the second embodiment.

[Third Method of Manufacturing Light Source Device]

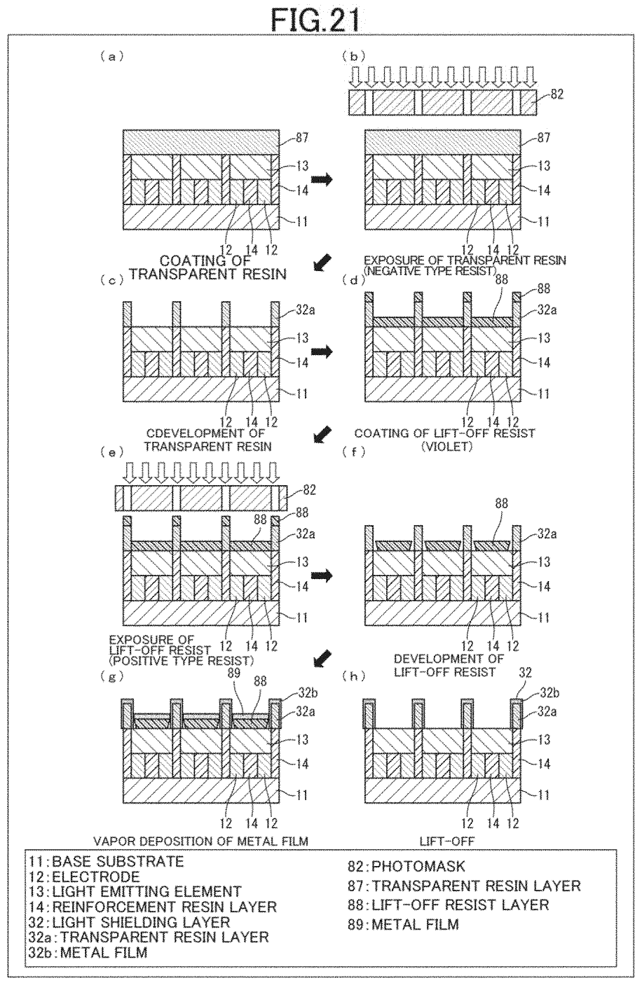

Still another method of manufacturing the light source device according to the present embodiment will be described. FIG. 21 is a longitudinal cross-sectional diagram illustrating still another method of manufacturing the light source device according to the present embodiment.

FIG. 21 corresponds to, for example, the method of manufacturing the light source device 9 (see FIG. 9) having the light shielding layer 32 and furthermore, can also be applied to methods of manufacturing the light source device 63 (see FIG. 16) and the light source device 64 (see FIG. 17) including the light shielding layer 43.

First, as illustrated in (a) of FIG. 21, a state is provided in which the electrodes 12, the light emitting elements 13, and the reinforcement resin layers 14 are provided on the base substrate 11. Next, the entire upper surface of the three light emitting elements 13 and the reinforcement resin layers 14 are coated with a transparent resin to form the transparent resin layer 87.

Next, the transparent resin layer 87 is subjected to an exposure step using a photomask 82 illustrated in (b) of FIG. 21, and a development step illustrated in (c) of FIG. 21 to form a transparent resin layer 32a of the light shielding layer 32. Here, a width of the transparent resin layer 32a is the same as the width of the reinforcement resin layer 14.

Next, as illustrated in (d) of FIG. 21, the upper surfaces of the three light emitting elements 13 and the upper surfaces of the transparent resin layers 32a are coated with a lift-off resist to form lift-off resist layers 88. Next, the lift-off resist layers 88 are subjected to an exposure step using a photomask 82 illustrated in (e) of FIG. 21 and a development step illustrated in (f) of FIG. 21, and thereby, the lift-off resist layers 88 on the upper surfaces of the reinforcement resin layers 14 are removed.

Next, as illustrated in (g) of FIG. 21, the metal film 89 is vapor-deposited on the upper surfaces and side surfaces of the reinforcement resin layers 14 and on the upper surfaces of the lift-off resist layers 88 on the light emitting element 13. The metal film 89 vapor-deposited on the reinforcement resin layers 14 becomes a metal film 32b of the light shielding layers 32. Thereby, the light shielding layer 32 is formed in which side surfaces and upper surface of the transparent resin layer 32a are covered with the metal film 32b. Next, as illustrated in (g) of FIG. 21, the lift-off resist layers 88 and the metal film 89 on the light emitting elements 13 are removed (lift-off step).

Thereafter, by repeating the same steps as the phosphor layer material coating step, the exposure step, and the development step illustrated in (d) to (f) of FIG. 19, the red phosphor layer 15 and the green phosphor layer 16 are formed.

In each step of the present manufacturing method, baking is performed at an appropriate temperature and time after application, after exposure, and after development, if necessary. Although the base layer 31 is not illustrated in the present embodiment, the base layer may be formed on the base substrate 11 as described in the second embodiment.

[Fourth Method of Manufacturing Light Source Device]

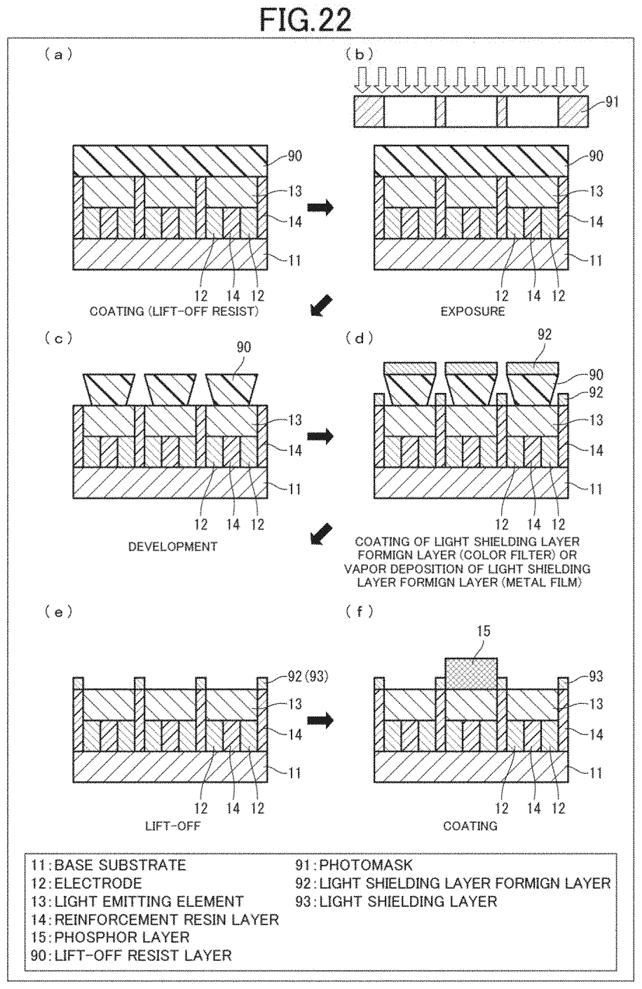

Still another method of manufacturing the light source device according to the present embodiment will be described. FIG. 22 is a longitudinal cross-sectional diagram illustrating still another method of manufacturing the light source device according to the present embodiment. FIG. 22 corresponds to, for example, the method of manufacturing the light source device 9 including the light shielding layer 32 (see FIG. 9), and furthermore, can also be applied to methods of manufacturing the light source device 63 (see FIG. 16) and the light source device 64 (see FIG. 17) including the light shielding layer 43.

First, as illustrated in (a) of FIG. 22, a state is provided in which the electrodes 12, the light emitting elements 13, and the reinforcement resin layers 14 are provided on the base substrate 11. Next, the entire upper surface of the three light emitting elements 13 and the reinforcement resin layers 14 are coated with a lift-off resist to form a lift-off resist layer 90.

Next, the lift-off resist layer 90 is subjected to an exposure step using a photomask 91 illustrated in (b) of FIG. 22 and a development step illustrated in (c) of FIG. 22 to remove the lift-off resist layer 90.

Next, as illustrated in (d) of FIG. 22, the upper surfaces of the three light emitting elements 13 and the upper surfaces of the reinforcement resin layers 14 are coated with, for example, a color filter material, or a metal film is vapor-deposited thereon, and thereby, the forming layer of light shielding layer 92 is formed.

Next, as illustrated in (e) of FIG. 22, the lift-off resist layers 90 on the light emitting elements 13 are removed (lift-off process), and thereby, only the forming layer of light shielding layers 92 are left on the reinforcement resin layers 14. The remaining forming layer of light shielding layer 92 become a light shielding layer 93. When the forming layer of light shielding layer 92 is formed by vapor deposition of a metal film, the light shielding layer 93 becomes a reflection layer.

Thereafter, the same steps as the phosphor layer material coating step, the exposure step, and the development step illustrated in (d) to (f) of FIG. 19 or (a) to (c) of FIG. 20 are performed to form the red phosphor layer 15 as illustrated in (f) of FIG. 22. Further, the green phosphor layer 16 is formed in the same manner.

In each step of the present manufacturing method, baking is performed at an appropriate temperature and time after application, after exposure, and after development, if necessary. Although the base layer 31 is not illustrated in the present embodiment, the base layer may be formed on the base substrate 11 as described in the second embodiment.

[Fifth Method of Manufacturing Light Source Device]

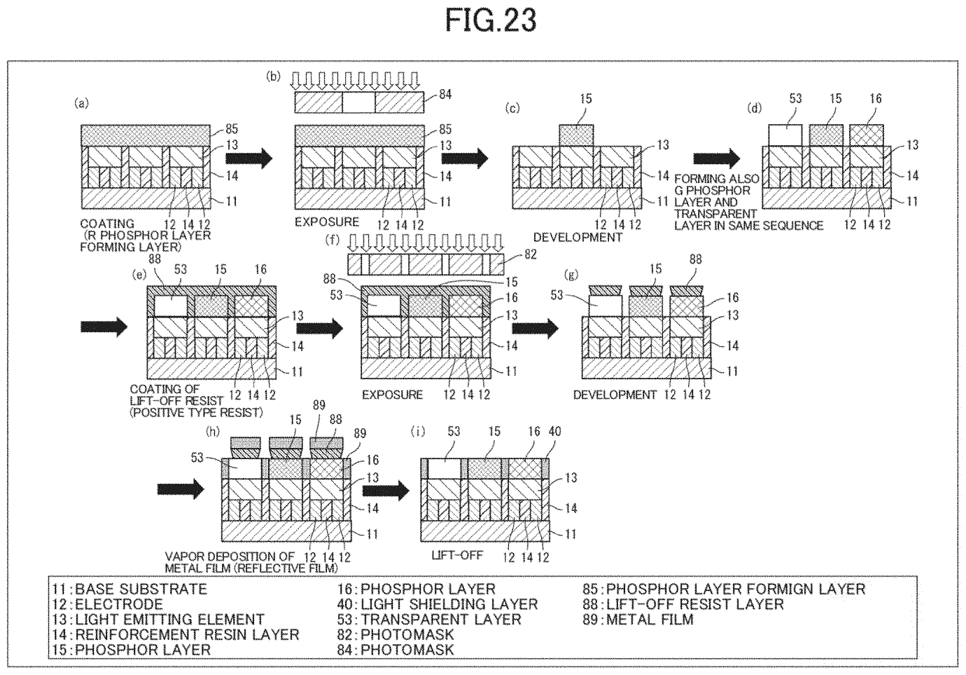

Still another method of manufacturing the light source device according to the present embodiment will be described. FIG. 23 is a longitudinal cross-sectional diagram illustrating still another method of manufacturing the light source device according to the present embodiment. FIG. 23 corresponds to, for example, the method of manufacturing the light source device 10 including the light shielding layer 40 (see FIG. 10), and furthermore, can also be applied to methods of manufacturing the light source devices 66, 67, and 61 (see FIGS. 11, 12, and 13) including the light shielding layer 40.

First, as illustrated in (a) of FIG. 23, a state is provided in which the electrodes 12, the light emitting elements 13, and the reinforcement resin layers 14 are provided on the base substrate 11. Next, the entire upper surface of the three light emitting elements 13 and the reinforcement resin layers 14 are coated with a red phosphor layer material to form a forming layer of phosphor layer 85 (phosphor layer material coating step).

Next, the red phosphor layer 15 is formed on the light emitting element 13 in a central portion through the exposure step for the forming layer of phosphor layer 85 using the photomask 84 illustrated in (b) of FIG. 23 and the development step illustrated in (c) of FIG. 23.

Thereafter, as illustrated in (d) of FIG. 23, the green phosphor layer 16 and a transparent layer 53 are formed on an upper surface of the light emitting element 13 adjacent to the light emitting element 13 on which the red phosphor layer 15 is formed, through the phosphor layer material coating step, the exposure step, and the development step described above.

Next, as illustrated in (e) of FIG. 23, the upper surfaces of the phosphor layers 15 and 16 and the transparent layer 53 and the upper surfaces of the reinforcement resin layers 14 are coated with a lift-off resist (positive resist) to form the lift-off resist layers 88.

Next, the lift-off resist layers 88 are subjected to the exposure step using the photomask 82 illustrated in (f) of FIG. 23 and the development step illustrated in (g) of FIG. 23, and thereby, the lift-off resist layers 88 on the upper surfaces of the reinforcement resin layers 14 are removed.

Next, as illustrated in (h) of FIG. 23, a metal films 89 serving as reflective films are vapor-deposited on the upper surfaces of the reinforcement resin layers 14 and the upper surfaces of the lift-off resist layers 88 on the phosphor layers 15 and 16 and the transparent layer 53. The metal films 89 vapor-deposited on the reinforcement resin layers 14 become the light shielding layers 40 (see (i) of FIG. 23).

Next, as illustrated in (i) of FIG. 23, the lift-off resist layers 88 and the metal films 89 on the phosphor layers 15 and 16 and the transparent layers 53 are removed (lift-off step).

In each step of the present manufacturing method, baking is performed at an appropriate temperature and time after application, after exposure, and after development, if necessary. Although the base layer 31 is not illustrated in the present embodiment, the base layer may be formed on the base substrate 11 as described in the second embodiment.

[Sixth Method of Manufacturing Light Source Device]

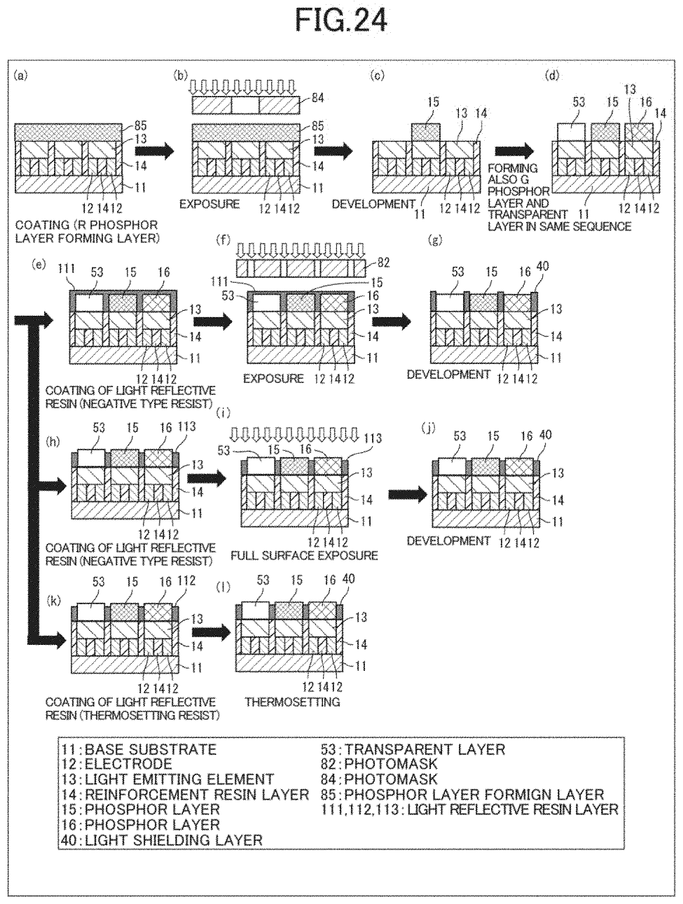

Still another method of manufacturing the light source device according to the present embodiment will be described. FIG. 24 is a longitudinal cross-sectional diagram illustrating still another method of manufacturing the light source device according to the present embodiment. FIG. 24 corresponds to, for example, the method of manufacturing the light source device 10 including the light shielding layer 40 (see FIG. 10), and furthermore, can also be applied to methods of manufacturing the light source devices 66, 67, and 61 (see FIGS. 11, 12, and 13) including the light shielding layers 40.

Steps (a) to (d) of FIG. 24 are the same as steps (a) to (d) of FIG. 23, and thus description thereof will be omitted.

As illustrated in (e) of FIG. 24, the upper surfaces of the phosphor layers 15 and 16 and the transparent layer 53 and the upper surfaces of the reinforcement resin layers 14 are coated with a light reflective resin (negative resist) to form a light-reflective resin layer 111.

Next, the light reflective resin layer 111 is subjected to an exposure step using the photomask 82 illustrated in (f) of FIG. 24 and a development step illustrated in (g) of FIG. 24, and thereby, the light reflective resin layer 111 on the upper surfaces of the phosphor layers 15 and 16 and the transparent layers 53 is removed. Thereby, a light source device is obtained.

### First Modification Example of Sixth Manufacturing Method

In the present manufacturing method, the steps illustrated in (e) to (g) of FIG. 24 may be replaced with the steps illustrated in (h) to (j) of FIG. 24. In this case, as illustrated in (h) of FIG. 24, the upper surfaces of the reinforcement resin layers 14 are coated with a light reflective resin to form light reflective resin layers 113 (negative resist), and next, the light reflective resin layers 113 are subjected to the exposure step without using the photomask 82 illustrated in (i) of FIG. 24 and the development step illustrated in (j) of FIG. 24, and thereby, the light reflective resin layer 111 on the upper surfaces of the phosphor layers 15 and 16 and the transparent layers 53 is removed. Thereby, a light source device is obtained.

### Second Modification Example of Sixth Manufacturing Method

In the present manufacturing method, the steps illustrated in (e) to (g) of FIG. 24 may be replaced with the steps illustrated in (k) to (l) of FIG. 24. In this case, as illustrated in (k) of FIG. 24, the upper surfaces of the reinforcement resin layers 14 are coated with a light-reflective resin (thermosetting resist) to form light reflective resin layers 112.

Next, the light reflective resin layers 112 are subjected to a heat curing step illustrated in (l) of FIG. 24 to cure the light reflective resin layers 112. Thereby, a light source device is obtained. As described above, the light reflective resin of the light-reflective resin layers 112 is a thermosetting type, and when the light reflective resin layers 112 can be coated between each layers (upper surface of the reinforcement resin layer 14) to have the same thickness as the phosphor layers 15 and 16 and the transparent layer 53, the light reflective resin layer 112 may be cured only by heat processing.

In each step of the present manufacturing method, baking is performed at an appropriate temperature and time after application, after exposure, and after development, if necessary. Although the base layer 31 is not illustrated in the present embodiment, the base layer may be formed on the base substrate 11 as described in the second embodiment.

[Seventh Method of Manufacturing Light Source Device]

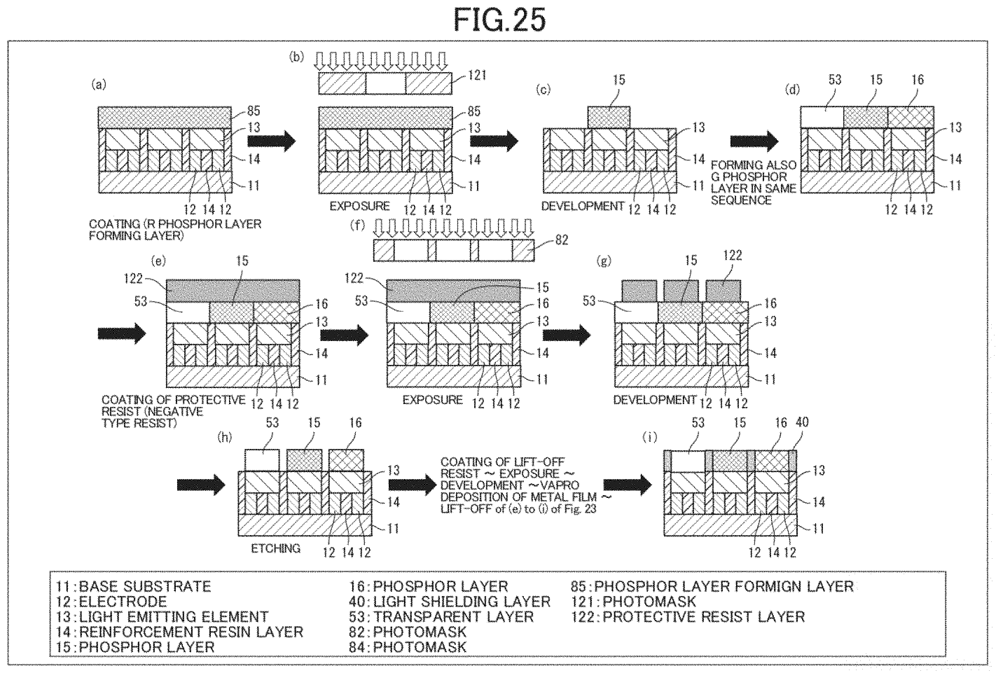

Still another method of manufacturing the light source device according to the present embodiment will be described. FIG. 25 is a longitudinal cross-sectional diagram illustrating still another method of manufacturing the light source device according to the present embodiment. For example, FIG. 25 corresponds to a method of manufacturing a light source device according to a modification example in which a yellow phosphor and any one of red, green, and blue color filters are formed on all light emitting elements in the light source device 10 including the light shielding layer 40 (see FIG. 10), and furthermore, can also be applied to a manufacturing method of the same modification example or the like of the light source devices 66, 67, and 61 (see FIGS. 11, 12, and 13) including the light shielding layer 40.

The steps from (a) to (d) of FIG. 25 are the same as the steps from (a) to (d) of FIG. 23 except for a part of FIG. 23, and thus, only differences therebetween will be described. In (b) of FIG. 25, a photomask 121 having a wide opening width is used instead of the photomask 84. Thereby, a width of the phosphor layer 15 extends to above the reinforcement resin layers 14 on both sides of the phosphor layer 15. This point is the same for the phosphor layer 16 and the transparent layer 53. Thereby, as illustrated in (d) of FIG. 25, a state is provided in which the phosphor layer 15 is in contact with the adjacent phosphor layer 16 and the transparent layer 53, and next, as illustrated in (e) of FIG. 25, the upper surfaces of the phosphor layers 15 and 16 and the transparent layer 53 are coated with a protective resist (negative resist) to form a protective resist layer 122.

Next, the protective resist layer 122 is subjected to an exposure step using the photomask 82 illustrated in (f) of FIG. 25 and a development step illustrated in (g) of FIG. 25, and thereby, the protective resist layer 122 of portions corresponding to the upper surface of reinforcement resin layer 14 is removed.

Next, as illustrated in (h) of FIG. 25, the protective resist layer 122 and the phosphor layers 15 and 16 and the transparent layers 53 of portions corresponding to the upper surfaces of the reinforcement resin layers 14 are removed by etching.

Next, as illustrated in (i) of FIG. 25, the light shielding layer 40 is formed on the reinforcement resin layer 14 by the respective steps of lift-off resist coating, exposure, development, metal film vapor deposition, and lift-off illustrated in (e) to (i) of FIG. 23, and thus, a light source device is obtained.

In each step of the present manufacturing method, baking is performed at an appropriate temperature and time after application, after exposure, and after development, if necessary. Although the base layer 31 is not illustrated in the present embodiment, the base layer may be formed on the base substrate 11 as described in the second embodiment.

[Eighth Method of Manufacturing Light Source Device]

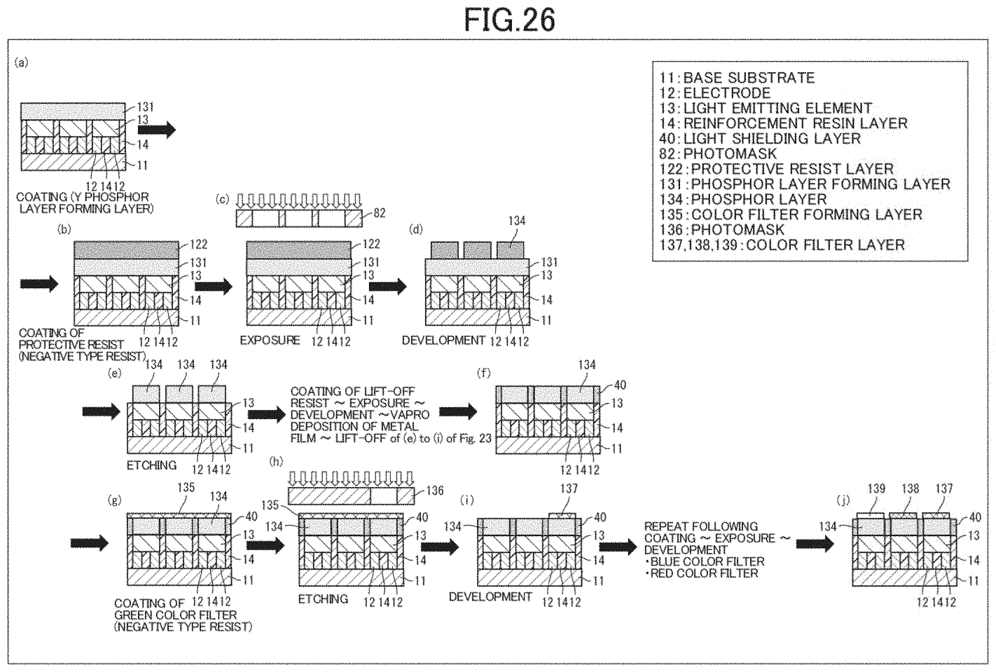

Still another method of manufacturing the light source device according to the present embodiment will be described. FIG. 26 is a longitudinal cross-sectional diagram illustrating still another method of manufacturing the light source device according to the present embodiment. For example, FIG. 26 corresponds to a method of manufacturing a light source device according to a modification example in which a yellow phosphor and any one of red, green, and blue color filters are formed on all light emitting elements in the light source device 10 including the light shielding layer 40 (see FIG. 10), and furthermore, can also be applied to a manufacturing method of the same modification example or the like of the light source devices 66, 67, and 61 (see FIGS. 11, 12, and 13) including the light shielding layer 40.

First, as illustrated in (a) of FIG. 26, the entire upper surface of the three light emitting elements 13 and the reinforcement resin layers 14 are coated with a phosphor layer material of a color to form a forming layer of phosphor layer 131 (phosphor layer material coating step).

Next, as illustrated (b) of FIG. 26, the upper surface of the forming layer of phosphor layer 131 is coated with a protective resist (negative resist) to form a protective resist layer 122.

Next, the protective resist layer 122 is subjected to an exposure step using a photomask 82 illustrated in (c) of FIG. 26 and a development step illustrated in (d) of FIG. 26, and thereby, the protective resist layer 122 of portions corresponding to the upper surfaces of the reinforcement resin layer 14 is removed.

Next, as illustrated in (e) of FIG. 26, the protective resist layer 122 and the forming layer of phosphor layer 131 of portions corresponding to the upper surfaces of the reinforcement resin layers 14 are removed by etching, and an independent phosphor layer 134 is formed on each light emitting element 13.

Next, as illustrated in (f) of FIG. 26, the light shielding layer 40 is formed on the reinforcement resin layer 14 through the respective steps of the lift-off resist coating, the exposure, the development, the metal film vapor deposition, and the lift-off illustrated in (e) to (i) of FIG. 23.

Next, as illustrated in (g) of FIG. 26, the upper surfaces of the phosphor layers 134 and the reinforcement resin layer 14 are coated with a green color filter material (negative resist) to form a color filter forming layer 135.

Next, the color filter forming layer 135 is subjected to an exposure step using a photomask 13 illustrated in (h) of FIG. 26 and a development step illustrated in (i) of FIG. 26, and thereby, a green color filter layer 137 is formed on one phosphor layer 134.

Thereafter, steps of (g) to (i) of FIG. 26 are repeated by using a red color filter material and a blue color filter material instead of the green color filter material, and as illustrated in (j) of FIG. 26, a red color filter layer 138 is formed on another phosphor layer 134, and furthermore, a blue color filter layer 139 is formed on the other phosphor layer 134, and thus, the light source device is obtained.

In each step of the present manufacturing method, baking is performed at an appropriate temperature and time after application, after exposure, and after development, if necessary. Although the base layer 31 is not illustrated in the present embodiment, the base layer may be formed on the base substrate 11 as described in the second embodiment.

### SUMMARY

A light source device according to a first aspect of the present invention includes respective light emitting elements for a red pixel, a green pixel, and a blue pixel, phosphor layers which are provided only on the light emitting element for the red pixel and the light emitting element for the green pixel, and parts of which are in contact with the light emitting elements at positions on emission sides of light from the light emitting elements, light shielding layers that are provided between the phosphor layers adjacent to each other and are different from the phosphor layers, and reinforcement layers provided between the light emitting elements adjacent to each other.

Light emitting elements are formed of, for example, GaN/InGaN, and one or both of a P electrode and an N electrode may have a mesa structure. The light emitting elements are hardly peeled off from a base substrate by a reinforcement layer. The reinforcement layer exists between the light emitting elements and between the light emitting elements and electrodes, and the base substrate, and peeling of the light emitting elements may be suppressed, and a configuration material is not limited and may be a reinforcement layer formed of an inorganic material.

In the light source device according to a second aspect of the present invention, in the above-described first aspect, the phosphor layers may be configured to include one or a plurality of phosphors configured by an organic material or an inorganic material. It is easy to form a phosphor layer with excellent adhesion to a light emitting element or a base layer and a light shielding layer, and a phosphor layer with an excellent color conversion capability, and it is possible to realize simultaneously suppression of peeling of the phosphor layer and an increase in the color conversion capability. Furthermore, a plurality of phosphor layers are provided, and thus, it is possible to control the color reproduction range and luminance.

In the light source device according to a third aspect of the present invention, in the above-described second aspect, the phosphor layer may be configured to be one kind or a plurality of kinds.

The reason for the above-described configuration is that it is easy to form a phosphor layer having excellent adhesion to a light emitting element or a base layer and a light shielding layer, and a phosphor layer with an excellent color conversion capability, and the phosphor layer is peeled off, and it is possible to realize simultaneously suppression of peeling of the phosphor layer and an increase in the color conversion capability. Because the phosphor layers may be different between red and green. If there is a case of “yellow phosphor+color filter”, there may be a case of “red phosphor+green phosphor (+color filter)”.

In the light source device according to a fourth aspect of the present invention, in the above-described third aspect, the light shielding layer may be configured to be formed not only between the phosphor layer but also on the phosphor layer.

Since a light shielding layer is formed between phosphor layers and also formed on the phosphor layers, the phosphor layers is hardly peeled off. Furthermore, a wavelength of light emitted from side surfaces of the phosphor layers is controlled. Since a red phosphor is excited by green light, crosstalk can be reduced by reducing light from the side surfaces of the phosphor layers configured by a green phosphor.

In the light source device according to a fifth aspect of the present invention, in the above-described fourth aspect, a material of the light shielding layer between the phosphor layers may be configured to be different from a material of the light shielding layer on the phosphor layer.

A phosphor layer where red and green lights are desired to be emitted may be a yellow phosphor. In fact, the following possibilities are considered.

Red light emitting pixel:

(1) Red phosphor,

(2) Red phosphor+red color filter

(3) Yellow phosphor+red color filter

(4) Red phosphor+dichroic mirror

(5) Red phosphor+dichroic mirror+red color filter

(6) Yellow phosphor+dichroic mirror+red color filter

Green light emitting pixel:

(1) Green phosphor,

(2) Green phosphor+green color filter

(3) Yellow phosphor+green color filter

(4) Green phosphor+dichroic mirror

(5) Green phosphor+dichroic mirror+green color filter

(6) Yellow phosphor+dichroic mirror+green color filter

In addition to this, the phosphor is not limited to one kind, and a plurality of kinds of phosphors, for example, two kinds of phosphors having different light emission colors such as “red phosphor+yellow phosphor” can be used in a red light emitting pixel, and a plurality of kinds of phosphors having the same light emission color such as “first red phosphor and second red phosphor” can be used.

In the light source device according to a sixth aspect of the present invention, in the above-described fifth aspect, each of the light emitting elements may be configured to include the phosphor layer or a resin layer.

In a case of a liquid crystal display, there are a plurality of conversion layers for one LED (blue LED+phosphor) that emits white light. Meanwhile, a pLED display using three or more light emitting elements such as a blue light emitting element, a green light emitting element, and a red light emitting element for each pixel has no conversion layer.

In the light source device according to a seventh aspect of the present invention, in the above-described sixth aspect, a different phosphor layer may be configured to be formed to overlap the light shielding layer on the phosphor layer.

By thickening a phosphor layer, it is possible to increase a color conversion capability.

In the light emitting device according to an eighth aspect of the present invention, in the above aspect 7, the light emitting element may be configured to have a mesa shape.

A light emitting device according to a ninth aspect of the present invention may be configured to include the light source device according to the above-described first aspect.

The light emitting device according to a tenth aspect of the present invention includes plurality of light emitting elements, phosphor layers provided for the respective light emitting elements, at positions on emission sides of light from the light emitting elements, a base layer that is provided between the light emitting elements and the phosphor layers and is different from the light emitting elements and the phosphor layers, light shielding layers that are provided between the phosphor layers adjacent to each other and are different from the phosphor layers, and reinforcement layers provided between the light emitting elements adjacent to each other.

A light emitting element is formed of, for example, GaN and InGaN. A light emitting element is hardly peeled off from a base substrate by a reinforcement layer, and the phosphor layer is hardly peeled off by increasing adhesion of the phosphor layer by a base layer. The reinforcement layer may be formed between the light emitting elements and between the light emitting element and an electrode, and the base substrate and may suppress peeling of the light emitting element, and a configuration material is not limited and may configure the reinforcement layer formed of an inorganic material.

In the light emitting device according to an eleventh aspect of the present invention, in the above-described tenth aspect, the phosphor layer may be configured to include one or a plurality of phosphors formed of an organic material or an inorganic material. By configuring a phosphor layer with plurality of layers as described above, it is easy to form a phosphor layer with excellent adhesion to a light emitting element or a base layer and a light shielding layer, and a phosphor layer with an excellent color conversion capability, and it is possible to realize simultaneously suppression of peeling of the phosphor layer and an increase in the color conversion capability. Furthermore, a plurality of phosphor layers are provided, and thus, it is possible to control the color reproduction range and luminance.

In the light emitting device according to a twelfth aspect of the present invention, in the above-described tenth aspect, one or a plurality of kinds of the phosphor layers may be configured to be provided.

The reason for the above-described configuration is that suppression of peeling of a phosphor layer and an increase in a color conversion capability can be realized simultaneously by simultaneously using the phosphor layer having excellent adhesion to a light emitting element or a base layer and a light shielding layer, and a phosphor layer with an excellent color conversion capability, and the phosphor layer is peeled off Further, the phosphor layer may be different between red and green in sub-pixels of each light emission color. If there is a case of “yellow phosphor+color filter”, there may be a case of “red phosphor+green phosphor”, “red phosphor+green phosphor+color filter”, “red phosphor+yellow phosphor”, “red phosphor+yellow phosphor+color filter”, “green phosphor+yellow phosphor”, “green phosphor+yellow phosphor+color filter”, or the like. By configuring the phosphor layer with a plurality of layers, the color reproduction range and the luminance can be controlled.

In the light emitting device according to a thirteenth aspect of the present invention, in the above-described tenth aspect, the light shielding layer may be configured to be formed not only on the phosphor layer but also on the phosphor layer.

Since a light shielding layer is formed between phosphor layers and also formed on the phosphor layers, the phosphor layers is hardly peeled off. Furthermore, a wavelength of light emitted from side surfaces of the phosphor layers is controlled. Since a red phosphor is excited by green light, crosstalk can be reduced by reducing light from the side surfaces of the phosphor layers configured by a green phosphor, and a color reproduction range of the light source device can be increased.

In the light emitting device according to a fourteenth aspect of the present invention, in the above-described thirteenth aspect, a material of the light shielding layer between the phosphor layers may be configured to be different from a material of the light shielding layer on the phosphor layer.

A phosphor layer of a portion where green light is desired to be emitted may be a yellow phosphor. In fact, the following possibilities are considered.

Red light emitting pixel:

(1) Red phosphor,

(2) Red phosphor+red color filter

(3) Yellow phosphor+red color filter

(4) Red phosphor+dichroic mirror

(5) Red phosphor+dichroic mirror+red color filter

(6) Yellow phosphor+dichroic mirror+red color filter

Green light emitting pixel:

(1) Green phosphor,

(2) Green phosphor+green color filter

(3) Yellow phosphor+green color filter

(4) Green phosphor+dichroic mirror

(5) Green phosphor+dichroic mirror+green color filter

(6) Yellow phosphor+dichroic mirror+green color filter

In addition to this, the phosphor is not limited to one kind, and a plurality of kinds of phosphors, for example, two kinds of phosphors having different light emission colors such as “green phosphor+yellow phosphor” can be used in a red light emitting pixel, and a plurality of kinds of phosphors having the same light emission color such as “first green phosphor and second green phosphor” can be used.

In the light emitting device according to a fifteenth aspect of the present invention, in the above-described tenth aspect, each light emitting element may be configured to include the phosphor layer or a resin layer.

In a case of a liquid crystal display, there are a plurality of conversion layers for one LED (blue LED+phosphor) that emits white light, that is, one white light emitting LED corresponds to a plurality of pixels A pLED display using three or more light emitting elements such as a blue light emitting element, a green light emitting element, and a red light emitting element for each pixel has no conversion layer. Meanwhile, the light source device according to the present application includes light emitting elements corresponding to the respective pixels, phosphor layers are formed on the light emitting elements corresponding to green and red, and in addition to this, a light shielding layer is formed between the respective color pixels.

In the light emitting device according to a sixteenth aspect of the present invention, in the above-described tenth aspect, the light emitting element may be configured to have a mesa shape.

In the light emitting device according to a seventeenth aspect of the present invention, in the above-described thirteenth aspect, a different phosphor layer may be configured to form to overlap the light shielding layer on the phosphor layer.

By thickening a phosphor layer, it is possible to increase a color conversion capability.

The present invention is not limited to the above-described embodiments, various modifications are possible within the scope to be described in claims, and embodiments obtained by appropriately combining the technical means respectively disclosed in other embodiments are also included in the technical scope of the present invention. Furthermore, new technical characteristics can be formed by combining the technical means respectively disclosed in the respective embodiments.

What is claimed is:

1. A light source device, comprising:
light emitting elements provided respectively for a red pixel, a green pixel, and a blue pixel;
phosphor layers which are provided only on the light emitting element for the red pixel and the light emitting element for the green pixel, and parts of which are in contact with the light emitting elements at positions on emission sides of light from the light emitting elements;
light shielding layers that are provided between the phosphor layers adjacent to each other and are different from the phosphor layers; and
reinforcement layers provided between the light emitting elements adjacent to each other.

2. The light source device according to claim 1, wherein the phosphor layers include one or a plurality of phosphors formed of an organic material or an inorganic material.

3. The light source device according to claim 2, wherein the phosphor layers are one kind or a plurality of kinds.

4. The light source device according to claim 3, wherein the light shielding layer is formed not only between the phosphor layers but also on the phosphor layer.

5. The light source device according to claim 4, wherein a material of the light shielding layer between the phosphor layers is different from a material of the light shielding layer on the phosphor layer.

6. The light source device according to claim 5, wherein each of the light emitting elements includes the phosphor layer or a resin layer.

7. The light source device according to claim 6, wherein a different phosphor layer is formed to overlap the light shielding layer on the phosphor layer.

8. The light source device according to claim 7, wherein the light emitting element has a mesa shape.

9. A light emitting device that uses the light source device according to claim 1.

10. A light source device, comprising:
a plurality of light emitting elements;
phosphor layers provided respectively for the light emitting elements, at positions on emission sides of light from the light emitting elements;
a base layer that is provided between the light emitting elements and the phosphor layers and is different from the light emitting elements and the phosphor layers;
light shielding layers that are provided between the phosphor layers adjacent to each other and are different from the phosphor layers; and
reinforcement layers provided between the light emitting elements adjacent to each other.

11. The light source device according to claim 10, wherein the phosphor layer includes one or a plurality of phosphors formed of an organic material or an inorganic material.

12. The light source device according to claim 10, wherein the phosphor layers are one kind or a plurality of kinds.

13. The light source device according to claim 10, wherein the light shielding layer is formed not only between the phosphor layers but also on the phosphor layer.

14. The light source device according to claim 13, wherein a material of the light shielding layer between the phosphor layers is different from a material of the light shielding layer on the phosphor layer.

15. The light source device according to claim 10, wherein each light emitting element includes the phosphor layer or a resin layer.

16. The light source device according to claim 10, wherein the light emitting element has a mesa shape.

17. The light source device according to claim 13, wherein a different phosphor layer is formed to overlap the light shielding layer on the phosphor layer.
